(19) United States
(12) Patent Application Publication
(10) Pub. No.: US 2006/0147750 A1
(43) Pub. Date: Jul. 6, 2006

(54) Organic electroluminescence device and display apparatus

(76) Inventors: Yasuharu Ujiie, Kanagawa (JP); Yoshihisa Miyabayashi, Kanagawa (JP); Naoyuki Ueda, Kanagawa (JP); Mari Ichimura, Kanagawa (JP); Ichinori Takada, Kanagawa (JP); Yukinari Sakamoto, Tokyo (JP); Tadahiko Yoshinaga, Kanagawa (JP); Shinichiro Tamura, Kanagawa (JP)

Correspondence Address: SONNENSCHEIN NATH & ROSENTHAL LLP;Sears Tower, Wacker Drive Station, P.O. Box 061080, Chicago, IL, 60606-1080, US

(21) Appl. No.: 11/257,281

(22) Filed: Oct. 24, 2005

(30) Foreign Application Priority Data
Oct. 29, 2004 (JP) P2004-315488
Oct. 29, 2004 (JP) P2004-315489

(51) Int. Cl. H01L 51/54; H05B 33/14; C09K 11/06

(52) U.S. Cl. 428/690; 428/917; 313/504; 313/506; 257/E51.051; 257/40; 257/88

(57) ABSTRACT

An organic electroluminescence device having excellent life characteristics and high reliability and a display apparatus using such a device are provided. In the organic electroluminescence device having organic thin film layers provided between a lower electrode and an upper electrode and including at least a luminescent layer, any one of the organic thin film layers (particularly, the luminescent layer) contains a styrylamine derivative represented by the general formula shown below.

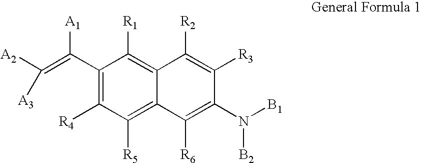

### CROSS REFERENCES TO RELATED APPLICATIONS

The present invention contains subject matter related to Japanese Patent Applications P2004-315488 and P2004-315489 filed in the Japanese Patent Office on Oct. 29, 2004, the entire contents of which being incorporated herein by reference.

### BACKGROUND OF THE INVENTION

The present invention relates to an organic electroluminescence device and a display apparatus, and more particularly to an organic electroluminescence device using a styrylamine derivative for an organic thin film layer and a display apparatus using the organic electroluminescence device.

Recently the research and development of a display apparatus with the use of an organic electroluminescence device has been actively pursued. The organic electroluminescence device is a self-luminous type display device that sandwiches a luminescent layer formed of an organic material between an anode and a cathode. A display apparatus that makes use of the organic electroluminescence device allows flat display by driving at low power consumption.

In order to realize full color display on such a display apparatus, it is necessary to use light emitting materials having high luminous efficiency, color purity, and reliability for the three primary colors (red, green, and blue colors). Particularly for a blue light emitting material among them, various methods have been proposed to enhance the luminous efficiency, color purity, and reliability as described below.

For example, achievement of a luminous efficiency of 3 to 3.4 Cd/A, chromaticity (0.154, 0.232), and half-life of ca. 4,000 hours (initial brightness; ca. 636 Cd/m²) has been reported for a device structure having 9,10-di-(2-naphthyl)-anthracene (AND) doped with 2,5,8,11-tetra-t-butylperylene (TBP) as a luminescent layer

Further, a device that makes use of styrylamine compounds has also been disclosed, and a luminous efficiency of ca. 3.4 Cd/A, and half-life of ca. 5,000 hours (initial brightness; 100 Cd/m²) has been reported for a device having DPVBi doped with BCzVBi as a luminescent layer (refer to Non-patent Document 2 below).

[Non-patent Document 1] Appl. Phys. Lett. Vol. 80, No. 17, p 3201-p 3203 (Apr. 29, 2002)

[Non-patent Document 2] Appl. Phys. Lett. Vol. 67, No. 26, p 3853-p 3855 (Dec. 25, 1995)

### SUMMARY OF THE INVENTION

In either of the organic electroluminescence devices having the structures described above, however, a half-life longer than 10,000 hours (initial brightness; 200 to 300 Cd/m²) that is necessary for realization of a display apparatus has not been achieved, and particularly, reliability has not been fully met for the organic electroluminescence devices.

The present invention addresses these and other problems to provide an organic electroluminescence device having excellent life characteristics, high reliability, and excellent luminous efficiency and a display apparatus using this device.

An organic electroluminescence device to satisfy the above features according to an embodiment of the present invention includes a styrylamine derivative represented by general formula 1 below in any one of organic thin film layers in the organic electroluminescence device in which the organic thin film layers having at least a luminescent layer are provided between an anode and a cathode.

Formula 15

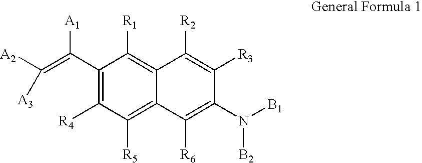

In this general formula 1, R₁ to R₆ each independently represents hydrogen, halogen, hydroxyl, cyano, nitro, amino, a saturated or unsaturated hydrocarbon group, a saturated or unsaturated hydrocarbon oxy group, a substituted or unsubstituted aryl group, a substituted or unsubstituted aryloxy group, a substituted or unsubstituted heterocyclic group, a saturated or unsaturated hydrocarbon amino group, or a substituted or unsubstituted arylamino group. A₁to A₃, B₁, and B₂ each independently represents hydrogen, a saturated or unsaturated hydrocarbon group, a substituted or unsubstituted aryl group, or a substituted or unsubstituted heterocyclic group. Adjacent groups of these R₁ to R₆, A₁ to A₃, B₁, and B₂ may join together to form a saturated or unsaturated carbon ring.

Particularly when at least one of the groups represented by A₁ to A₃ in the general formula 1 is substituted by an aryl group or when a condensed ring having three or more rings including the naphthalene portion is formed by joining mutually at least a pair of adjacent substituents of R₁ to R₆, the length of conjugation including also the double bond is further enlarged, and thus, further molecular stabilization may be attained.

For example, when at least one of the groups represented by A₁ to A₃ in the general formula 1 is substituted by an aryl group, at least one of A₁ to A₃ may be an aryl group represented by general formula 2 shown below.

Formula 16

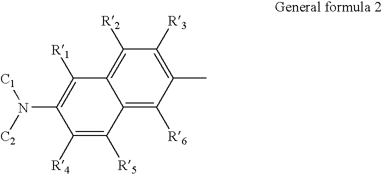

Preferably, A₂ in the general formula 1 is replaced with the aryl group of the general formula 2 to form a styrylamine derivative that is the E-isomer of general formula 3 shown below or the z-isomer thereof, thereby efficiently enlarging the length of conjugation to attain the molecular stabilization. Particularly, the length of conjugation can be most effectively enlarged by choosing the E-isomer.

Formula 17

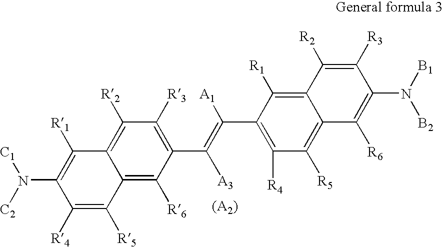

Here, R′₁ to R′₆ in the above general formulae 2 and 3 are defined similarly to R₁ to R₆ in the above general formula 1. Further, C₁ and C₂ in the general formulae 2 and 3 are defined similarly to B₁ and B₂ in the above general formula 1.

As a more specific structure in the general formula 3, a styrylamine derivative represented by general formula 4 below is shown. Although the E-isomer is shown in the general formula 4, at least one kind of the E-isomer and Z-isomer may be contained.

Formula 19

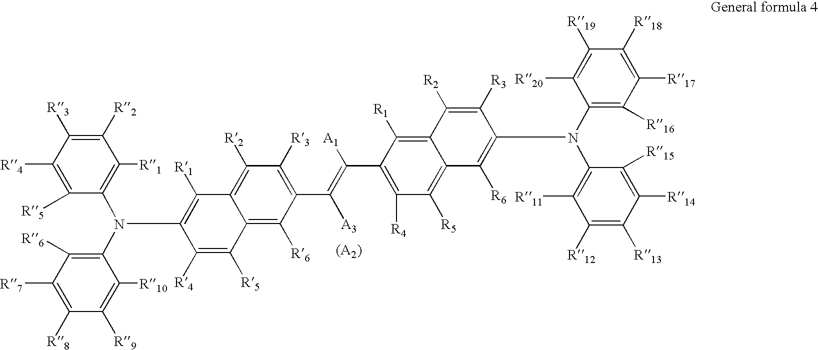

In this general formula 4, R″₁ to R″₂₀ each independently represents hydrogen, halogen, hydroxyl, cyano, nitro, amino, a saturated or unsaturated hydrocarbon group, a saturated or unsaturated hydrocarbon oxy group, a substituted or unsubstituted aryl group, a substituted or unsubstituted aryloxy group, a substituted or unsubstituted heterocyclic group, a substituted or unsubstituted hydrocarbon amino group, or a substituted or unsubstituted arylamino group. Adjacent groups other than hydrogen, halogen, cyano, and nitro groups in these R″₁ to R″₂₀ may join to each other to form a saturated or unsaturated hydrocarbon ring.

Since the styrylamine derivatives explained with the use of the general formulae 1 to 4 as described above are used as an organic thin film layer, it is desired for the above-described R₁ to R₆, R′₁ to R′₆, A₁ to A₃, B₁, B₂, C₁, C₂, and R″₁to R″₂₀ to be designed so that the total molecular weights may not become larger than 1,000 in consideration that these are used, for example, as a material for film formation by vapor deposition in the production process.

Based on this, when R₁ to R₆ in the above-described general formula 1 are carbon-carrying groups, it is preferred that the carbon number of each group of R₁ to R₆ is as follows: hydrocarbon and hydrocarbon oxy group; from 1 to 20 carbon atoms, aryl and aryloxy group; from 6 to 25 carbon atoms, heterocyclic group; from 2 to 25 carbon atoms, hydrocarbon amino group; from 1 to 8 carbon atoms, and arylamino group; from 6 to 35 carbon atoms. Further, when A₁ to A₃, B₁, and B₂ in the general formula 1 are carbon-carrying groups, it is preferred that the carbon number of each of the groups is as follows: saturated or unsaturated hydrocarbon group; from 1 to 20 carbon atoms, substituted or unsubstituted aryl group; from 6 to 45 carbon atoms, and substituted or unsubstituted heterocyclic group; from 2 to 30 carbon atoms.

In addition, when R′₁ to R′6, C₁, C₂, and R″₁ to R″₂₀ in the general formulae 2 to 4 are carbon-carrying groups, the carbon number of each of these groups is designed within the range of the carbon number defined above for A₁ to A₃ in the general formula 1 when these are carbon-carrying groups.

As specific examples of the styrylamine derivatives explained as above with the use of the general formulae 1 to 4, the following structures are exemplified. It should be noted that Me indicates methyl group and n-Pr indicates normal propyl group in the structural formulae.

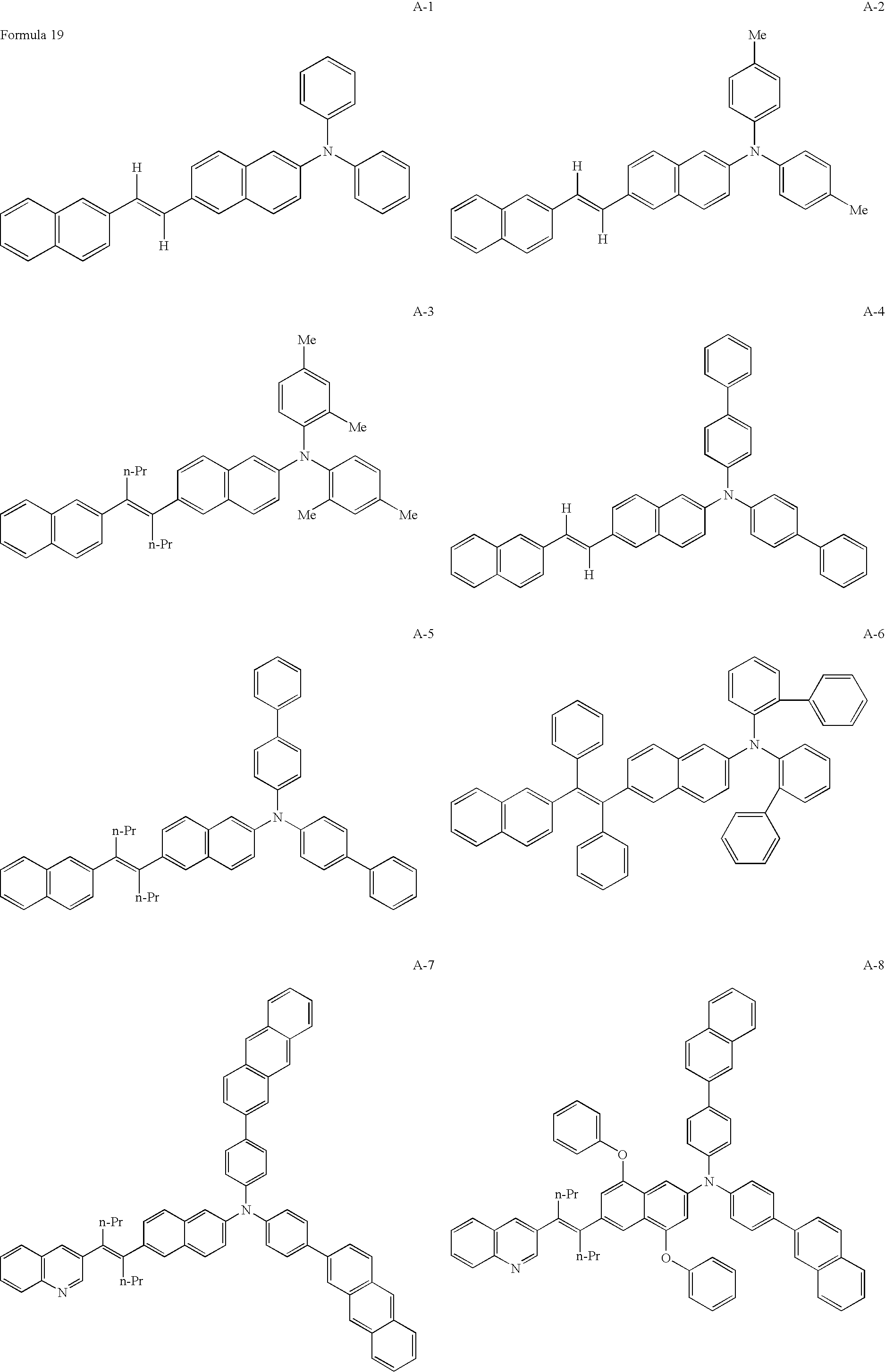

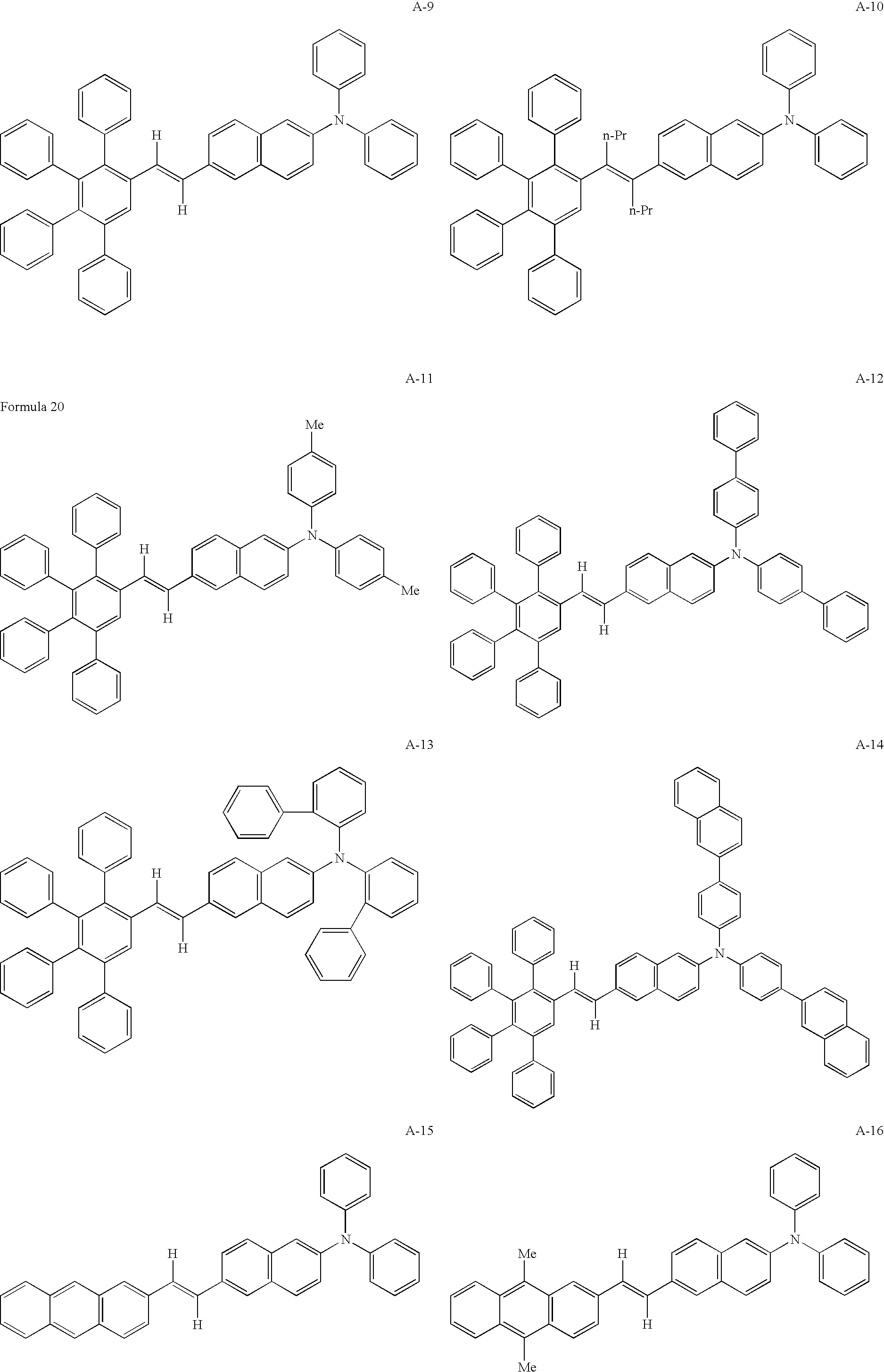

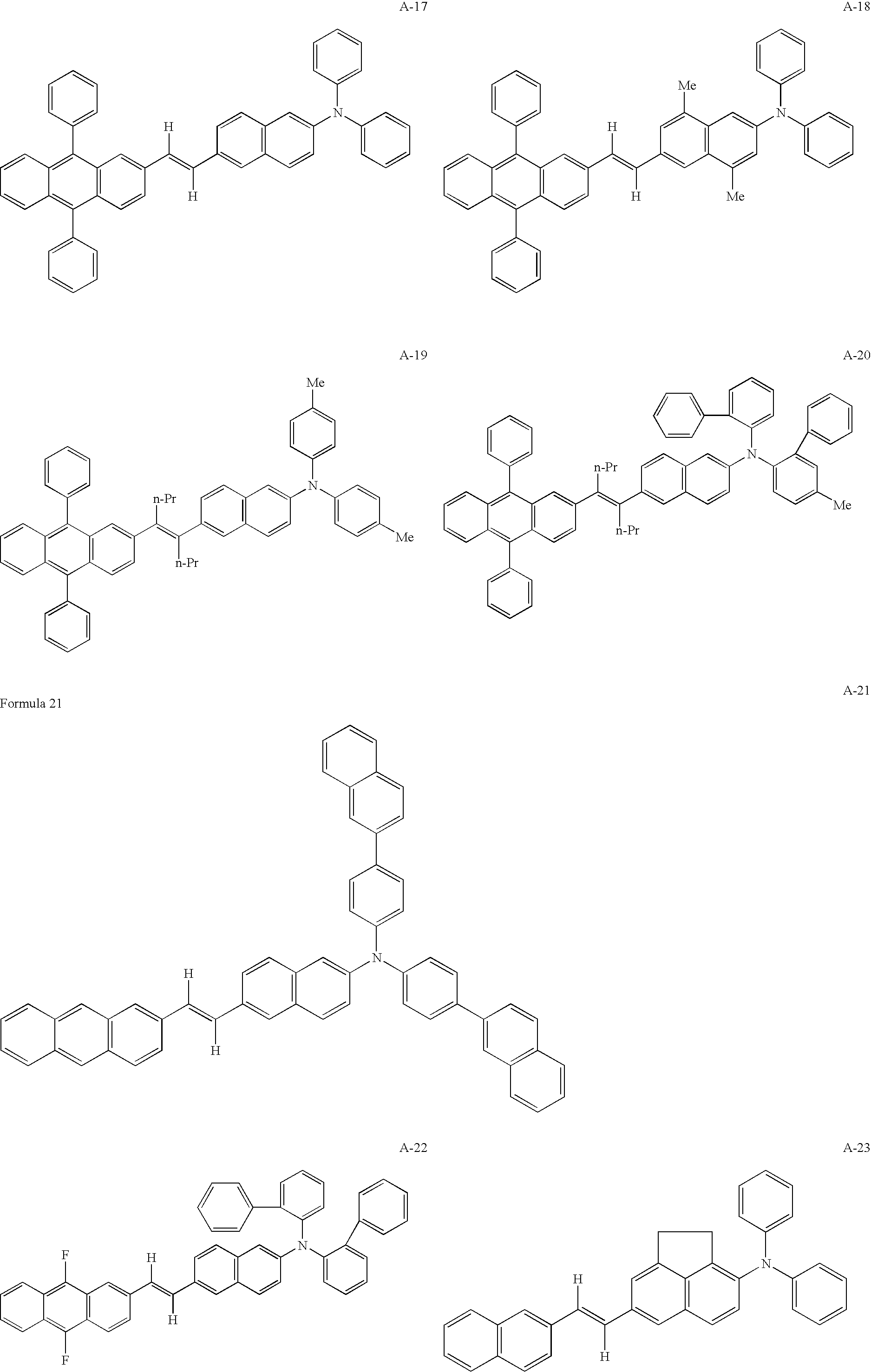

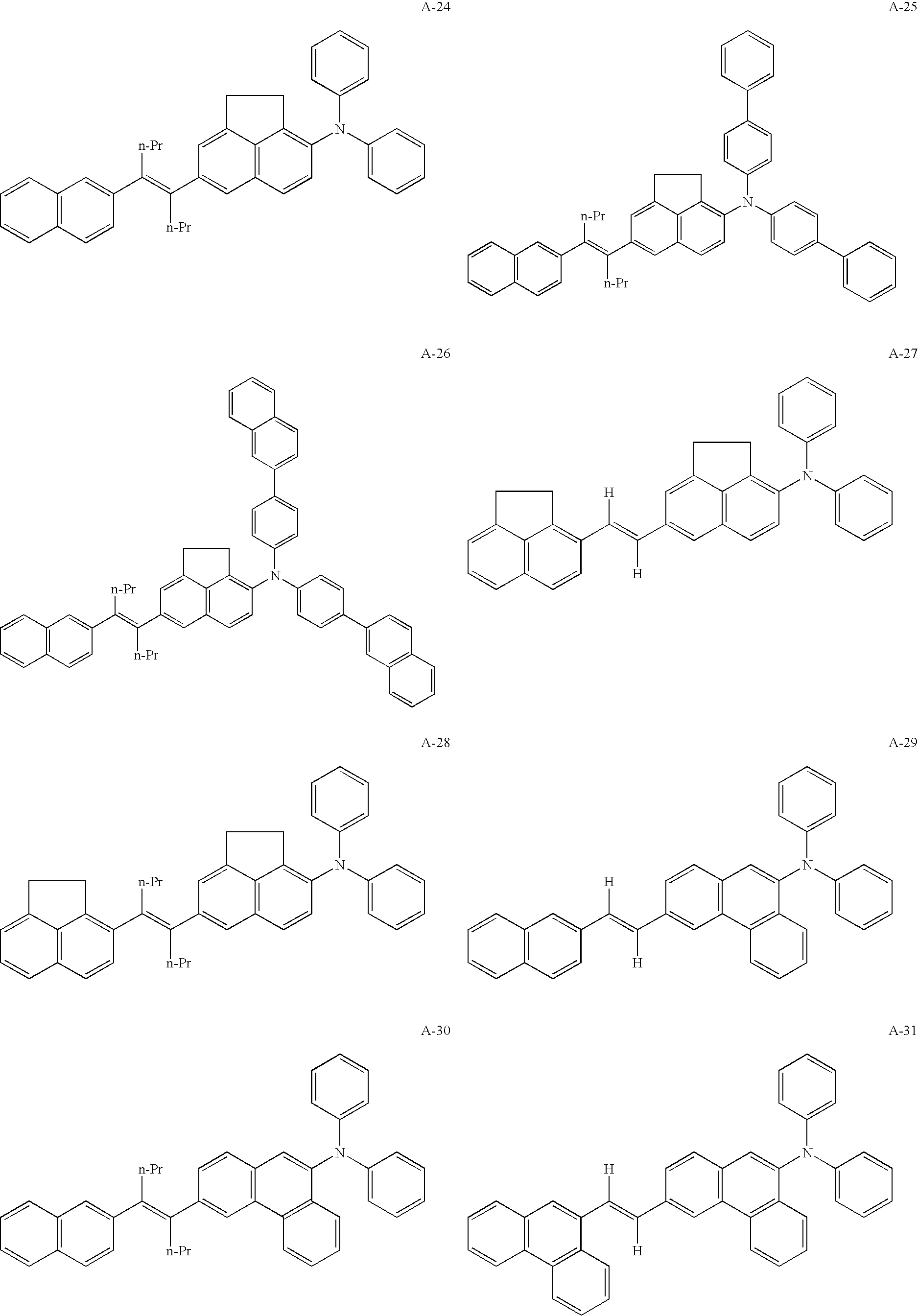

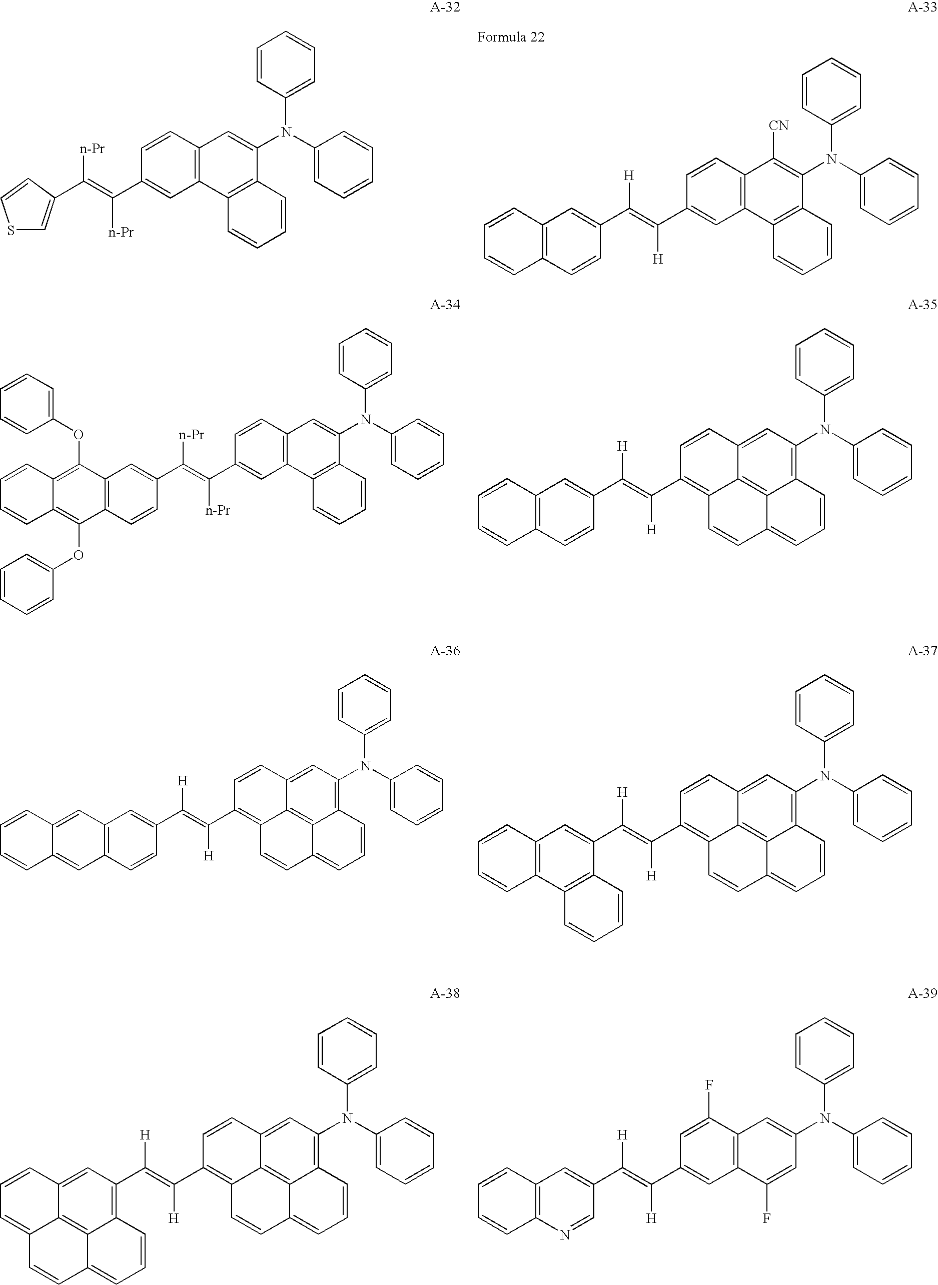

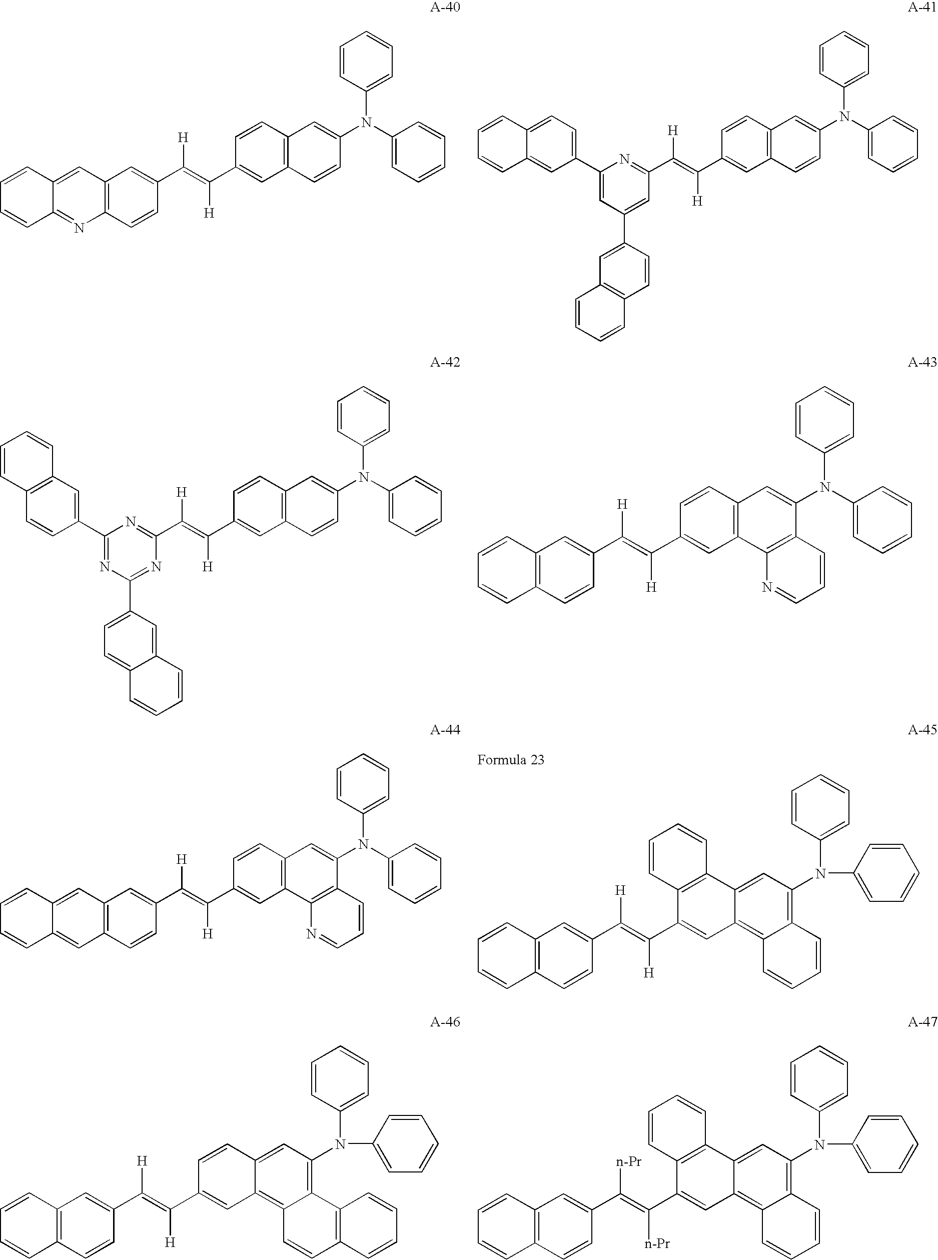

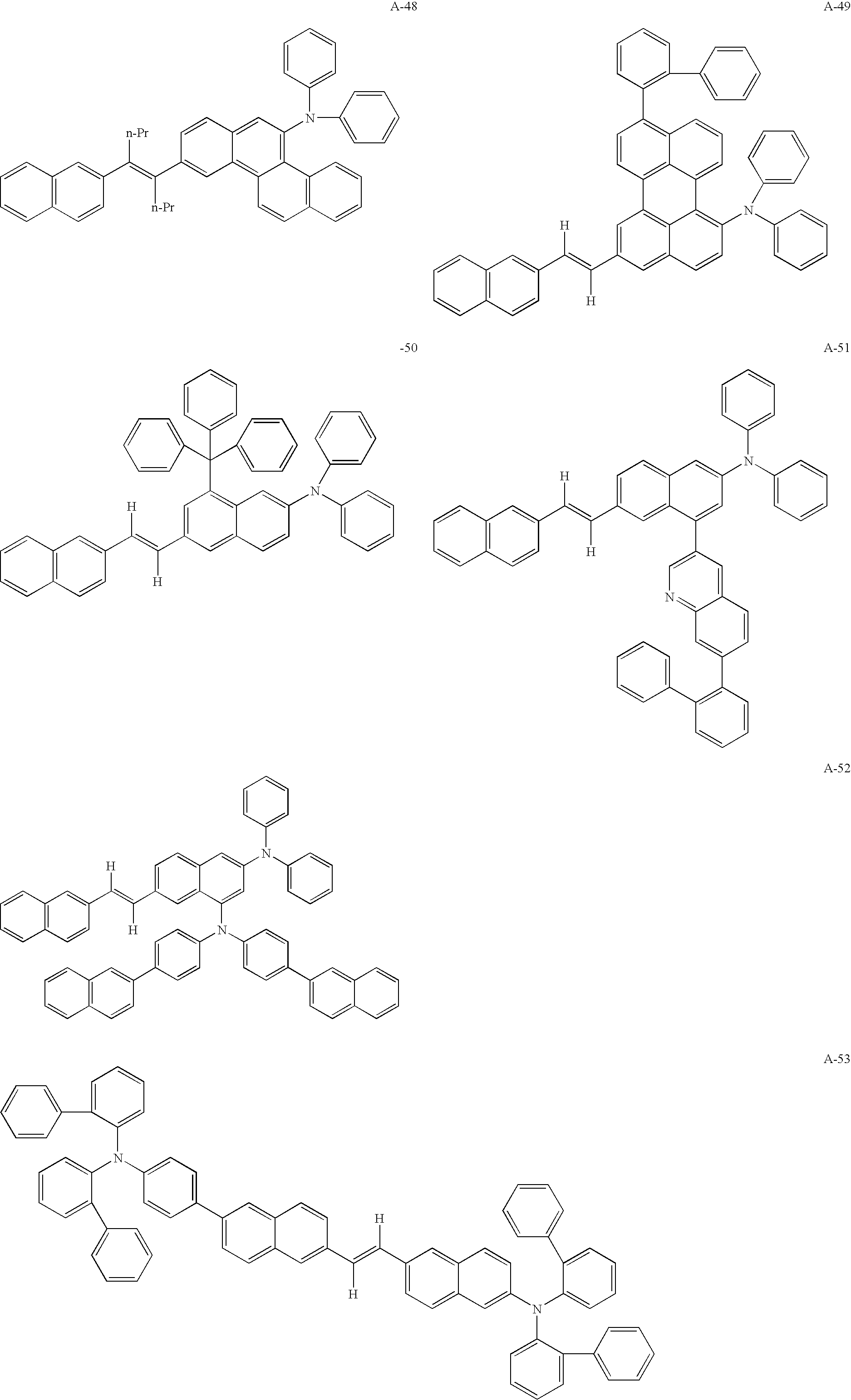

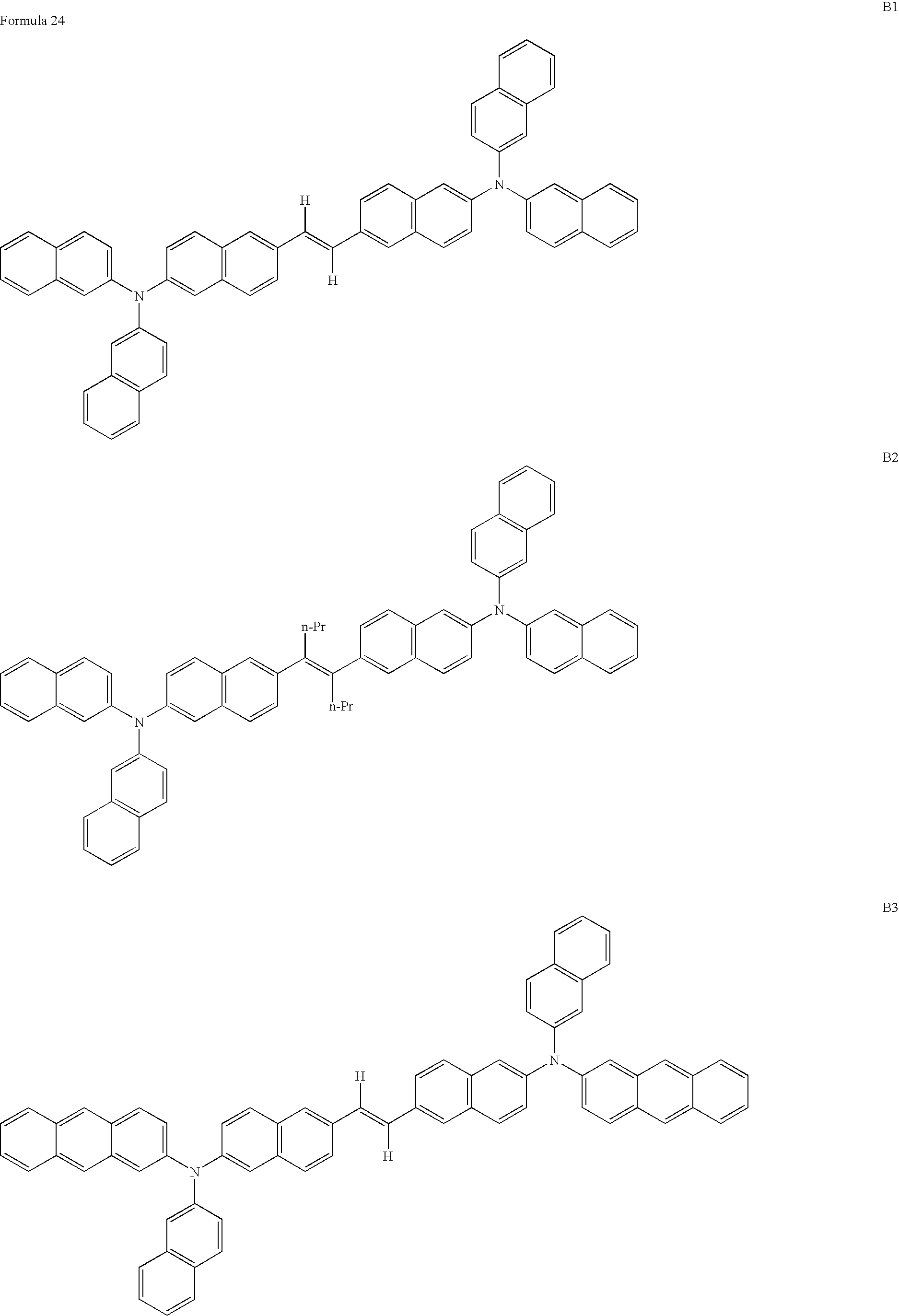

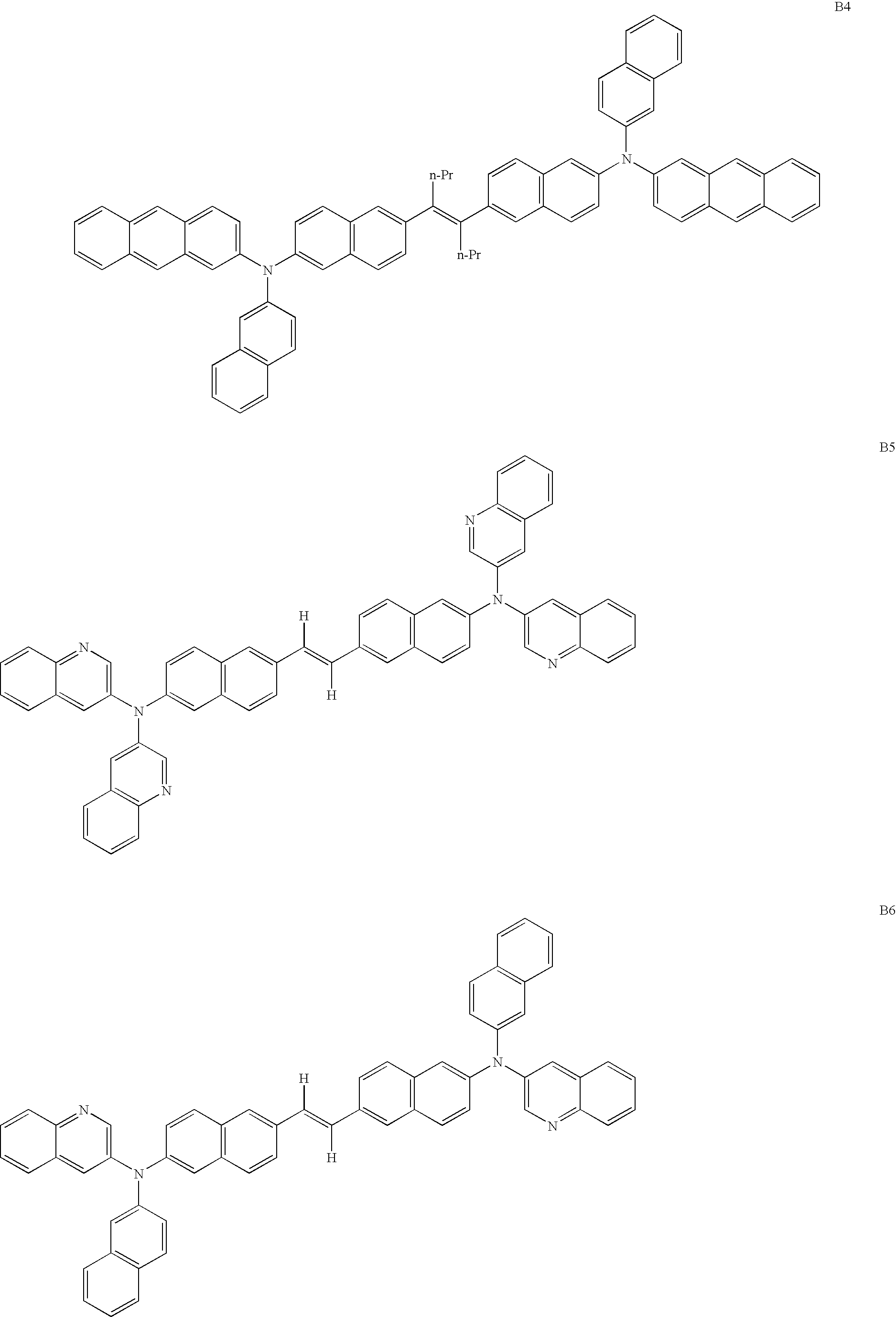

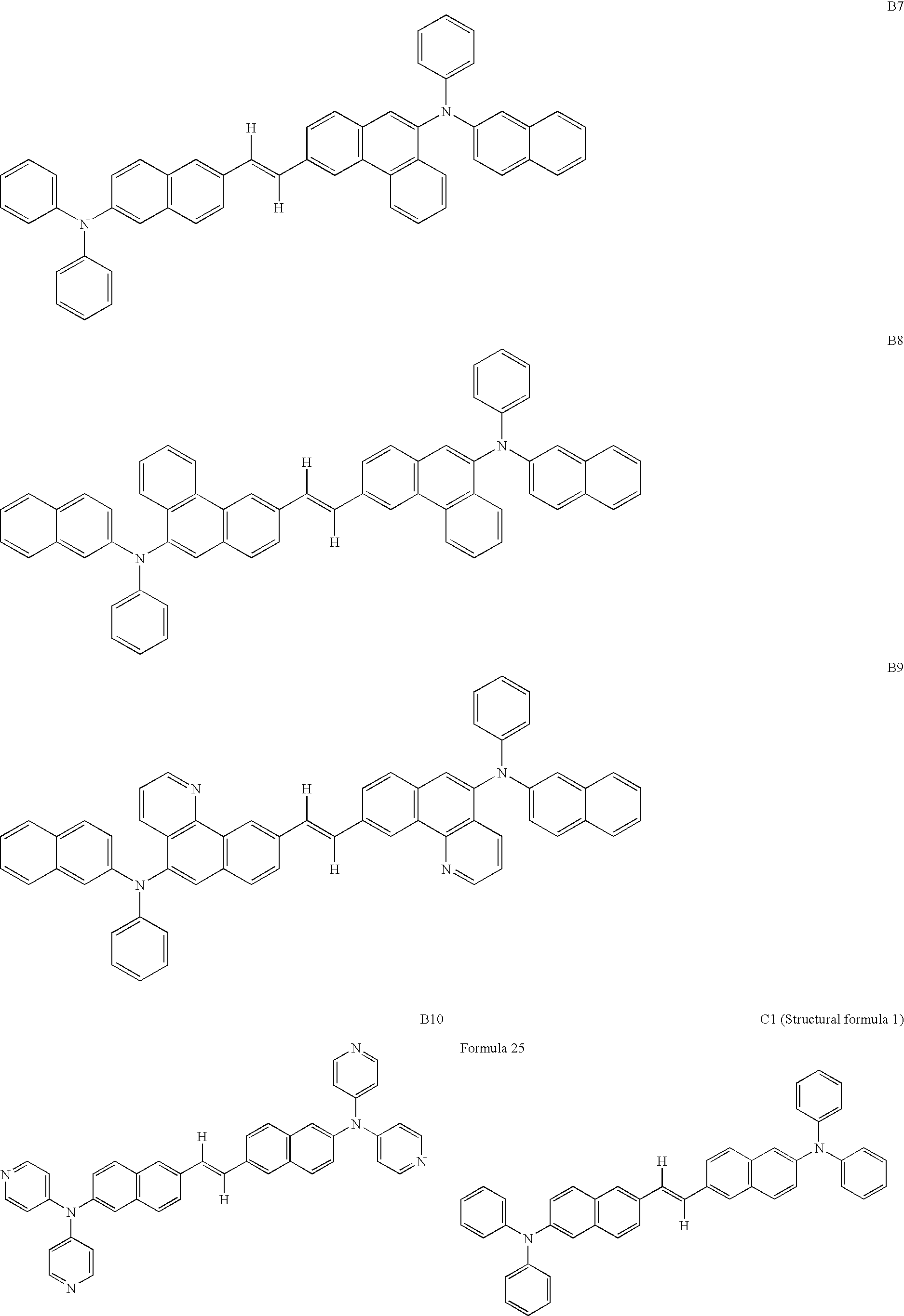

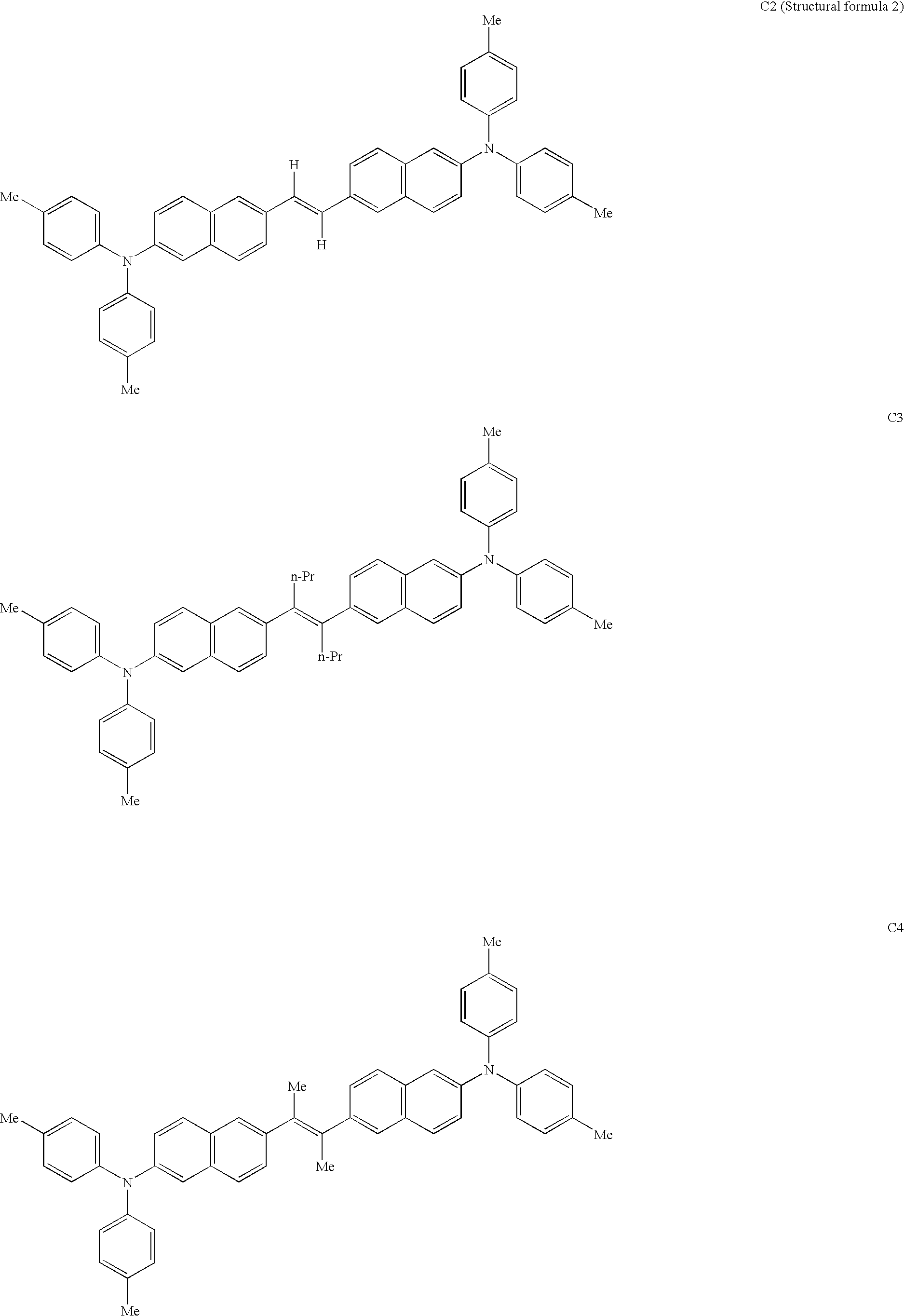

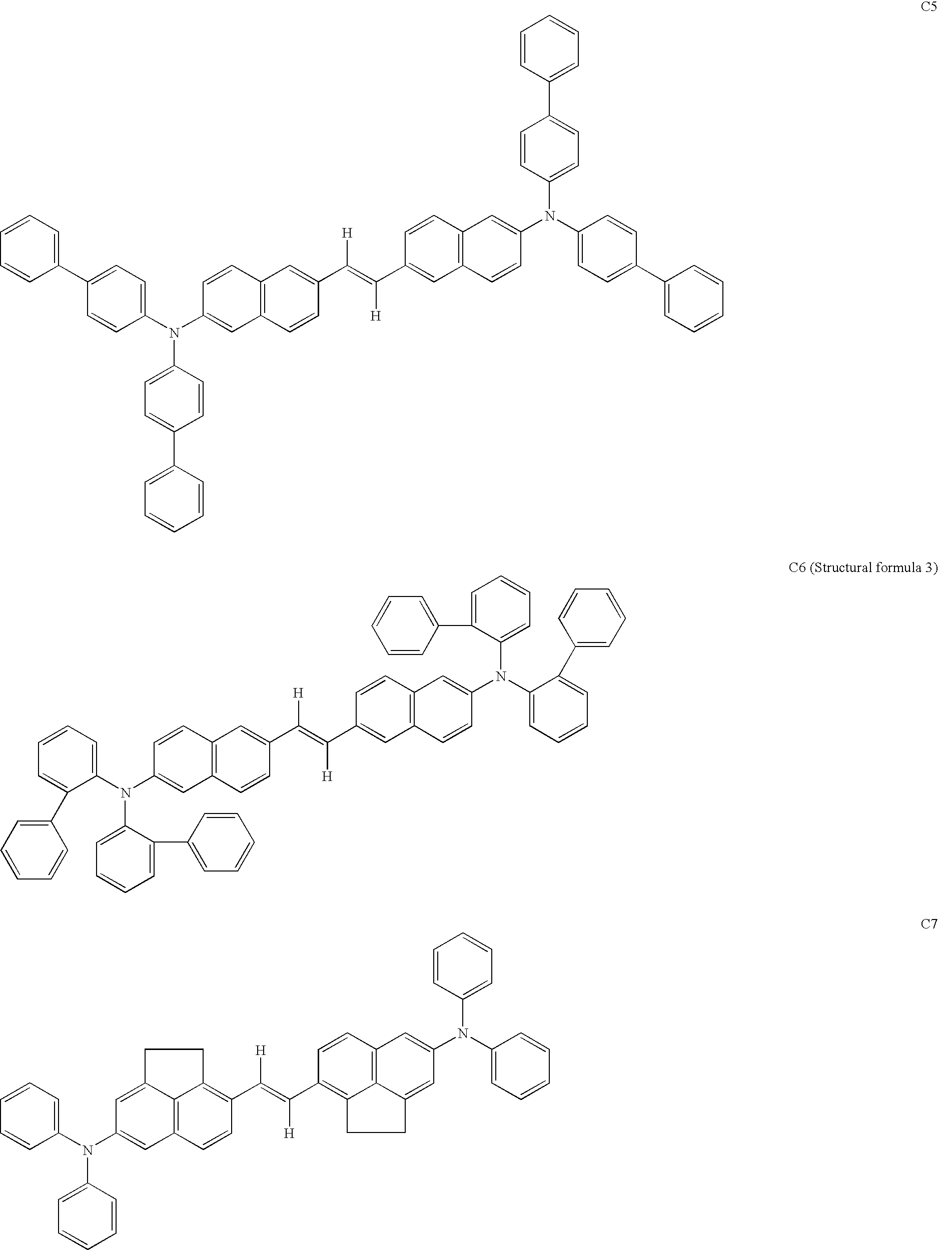

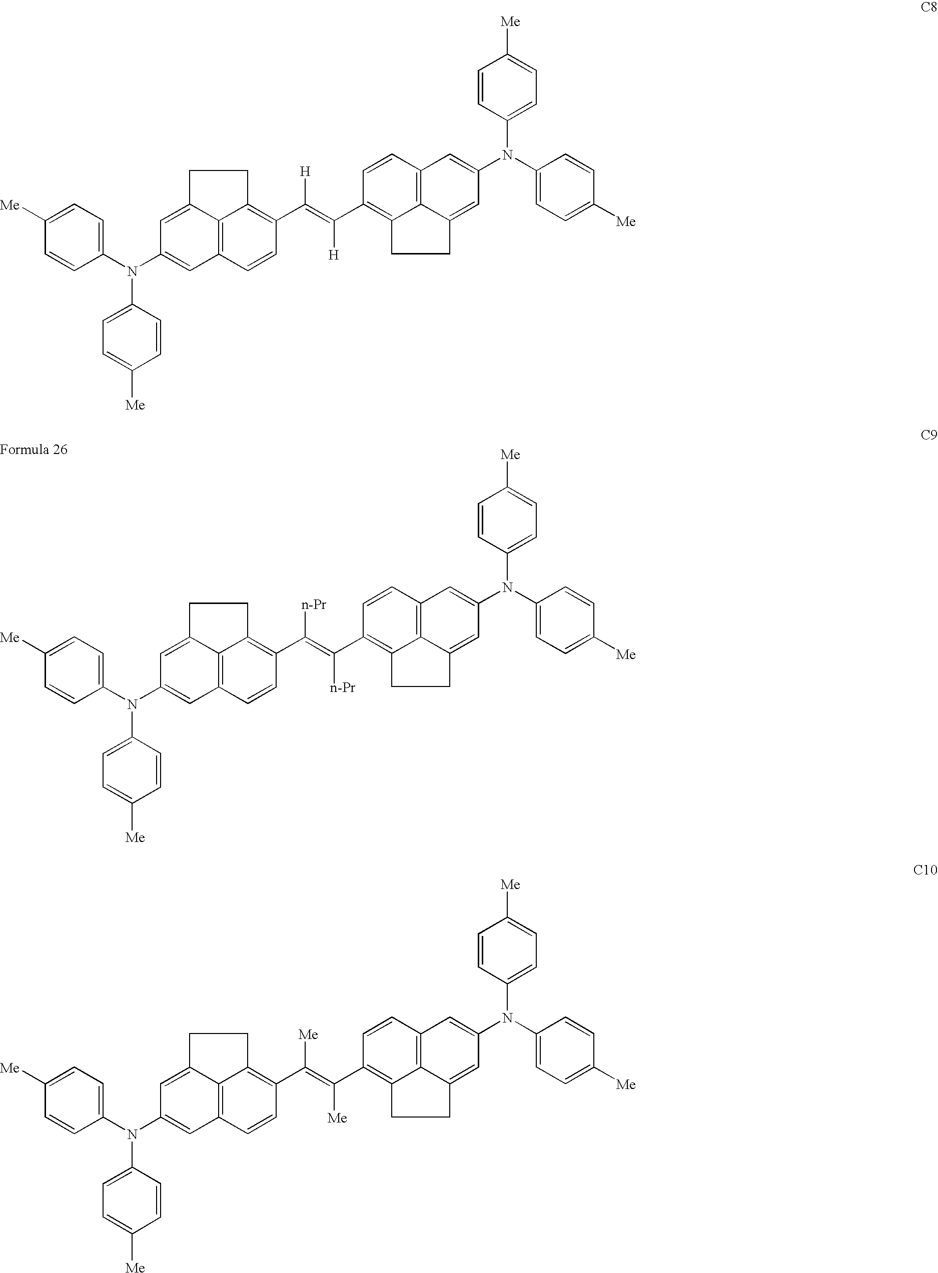

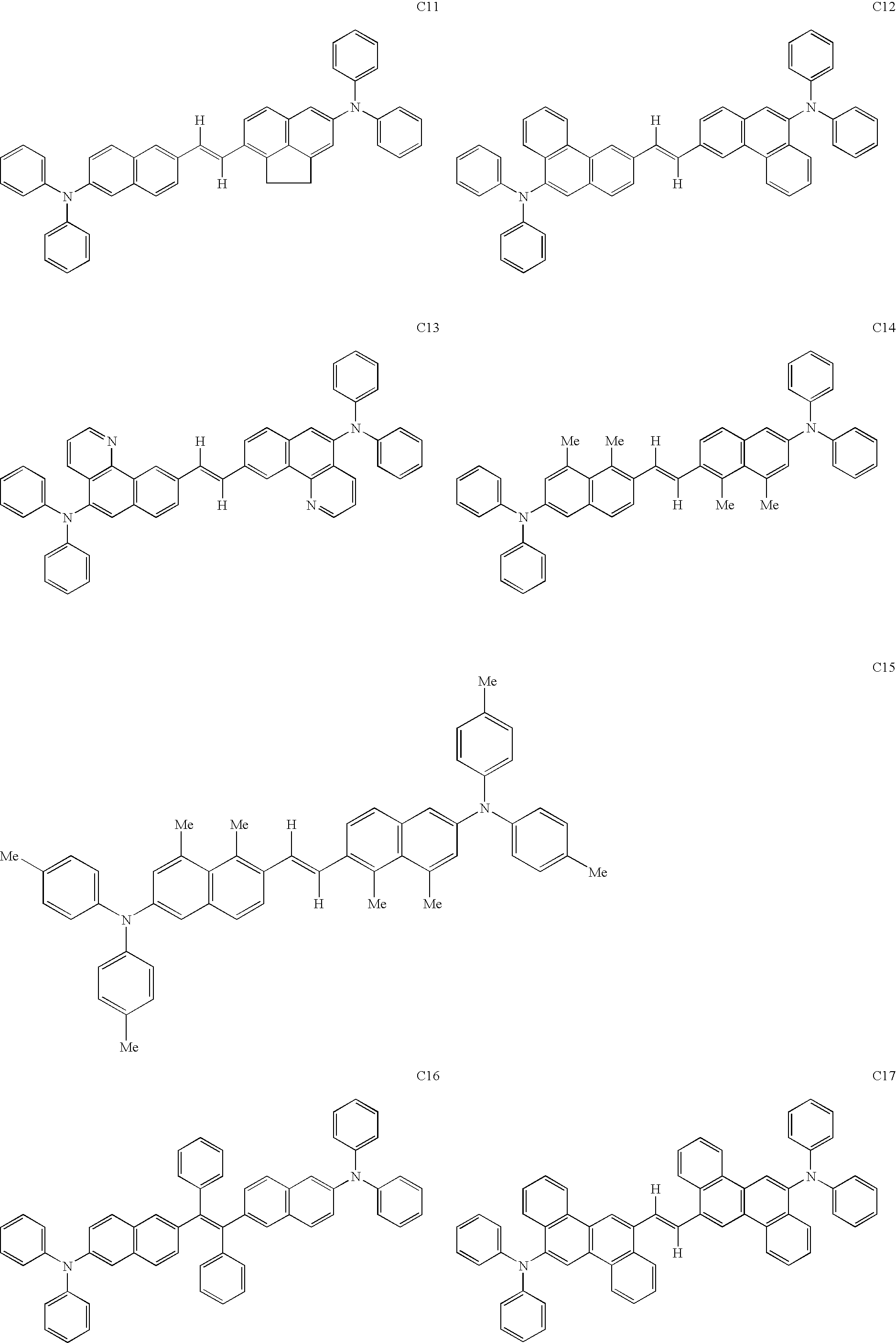

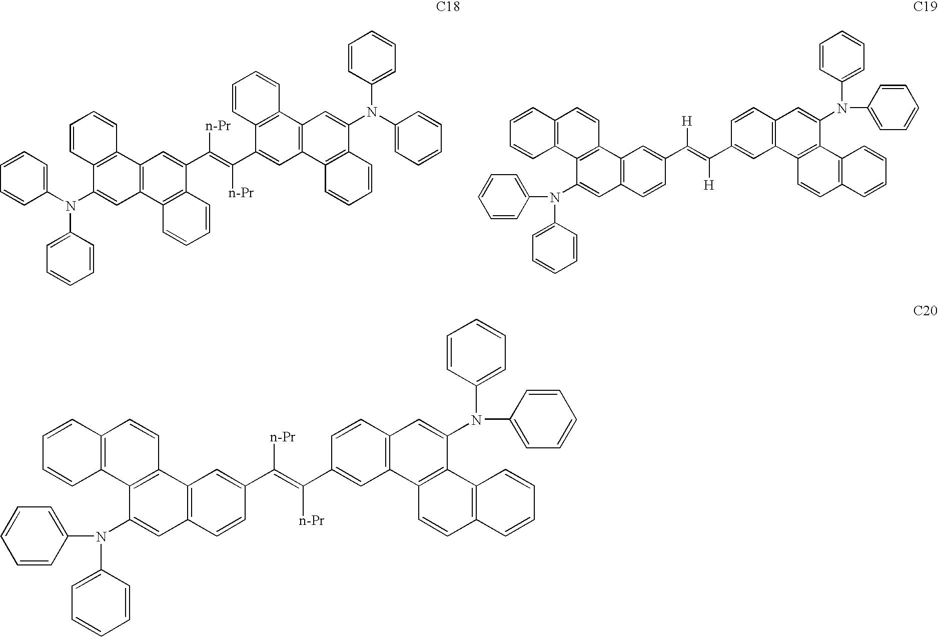

In the styrylamine derivatives represented by the above general formula 1, arylene derived from naphthalene is placed between the double bond and the amino group that are bound at the positions 2 and 6 of the naphthalene ring respectively, thereby increasing delocalization energy of π electrons of the double bonds. In this way, chemical stability of the whole molecule is achieved for the styrylamine derivatives represented by the general formula 1. Accordingly, deterioration of an organic electroluminescence device that makes use of such a styrylamine derivative for an organic thin film layer can be suppressed.

The styrylamine derivatives explained by the use of the general formulae 1 to 4 are preferably used as a material forming a luminescent layer in organic thin film layers of an organic electroluminescence device. Thereby, an attenuation factor (relating to luminescence) in the organic electroluminescence device can be made low. Since these styrylamine derivatives are highly fluorescent materials, high fluorescence efficiency and fluorescence at initial brightness can be obtained.

Since the fluorescence spectra of the styryl compounds have peaks at short wavelengths, blue light emission having high color purity can be obtained by using the styrylamine derivatives explained with the use of the general formulae 1 to 4 as a material forming a blue light emitting luminescent layer of an organic electroluminescence device.

When the styrylamine derivatives explained with the use of the general formulae 1 to 4 are used for a blue light emitting layer of an organic electroluminescence device and when R₁ to R₆ in the general formula 1 described above are carbon-carrying groups, it is preferred that the carbon number of each group of R₁ to R₆ is as follows: hydrocarbon and hydrocarbon oxy group; from 1 to 6 carbon atoms, aryl and aryloxy group; from 6 to 12 carbon atoms, heterocyclic group; from 2 to 10 carbon atoms, hydrocarbon amino group; from 1 to 8 carbon atoms, and arylamino group; from 6 to 35 carbon atoms. Further, when A₁ to A₃ are carbon-carrying groups, it is preferred that the carbon number of each of these groups is as follows: hydrocarbon group; from 1 to 20 carbon atoms, aryl group; from 6 to 45 carbon atoms, and heterocyclic group; from 2 to 30 carbon atoms. Furthermore, when B₁ and B₂ are carbon-carrying groups, it is preferred that the carbon number of each of these groups is as follows: aryl group; from 6 to 15 carbon atoms, and heterocyclic group; from 2 to 15 carbon atoms.

In addition, it is desirable that a styrylamine derivative having the structure described above is introduced in the luminescent layer at a proportion lower than 50% by volume, that is, as a guest.

The present invention is also a display apparatus formed by arranging on a substrate a plurality of organic electroluminescence devices having the above-described luminescent layer provided between an anode and a cathode.

In such a display apparatus, the display apparatus is constructed by the use of an organic electroluminescence device having a low attenuation factor in which deterioration of an organic thin film layer is suppressed. When this organic electroluminescence device is used as a specific color light emitting device (blue light emitting device), full color display becomes possible by combining with other color light emitting devices (for example, red light emitting device and green light emitting device).

As explained in the foregoing, according to the embodiment of the present invention, it becomes possible to obtain an organic electroluminescence device having suppressed deterioration of an organic thin film layer, excellent life characteristics, high reliability, and excellent luminous efficiency by forming the organic thin film layer with the styrylamine derivatives shown in the general formula 1 having excellent chemical stability and an display apparatus with the use thereof.

### BRIEF DESCRIPTION OF THE DRAWINGS

Embodiments of the present invention will be described in detail based on the following figures, wherein:

FIG. 1 is a cross sectional view showing the main part of an embodiment of an organic electroluminescence device and a display apparatus;

FIG. 2 shows time course changes in absorption spectrum and fluorescence spectrum of a compound 1, where FIG. 2-1 is an absorption spectrum of the compound 1 after 15 min, FIG. 2-2 is a fluorescence spectrum of the compound 1 after 15 min, FIG. 2-3 is an absorption spectrum of the compound 1 after 2 days, and FIG. 2-4 is a fluorescence spectrum of the compound 1 after 2 days;

FIG. 3 shows a NMR spectrum of an intermediate 11 synthesized in a synthetic example 1;

FIG. 4 shows a NMR spectrum of an intermediate 13 synthesized in the synthetic example 1;

FIG. 5 shows a NMR spectrum of a styrylamine derivative C1 synthesized in the synthetic example 1;

FIG. 6 shows a NMR spectrum of an intermediate 14 synthesized in a synthetic example 2;

FIG. 7 shows a NMR spectrum of an intermediate 15 synthesized in the synthetic example 2;

FIG. 8 shows a NMR spectrum of an intermediate 16 synthesized in the synthetic example 2;

FIG. 9 shows a NMR spectrum of a styrylamine derivative C2 synthesized in the synthetic example 2;

FIG. 10 shows a NMR spectrum of an intermediate 18 synthesized in a comparative example;

FIG. 11 shows a NMR spectrum of the compound 1 synthesized in the comparative example;

FIG. 12 shows an absorption spectrum and a fluorescence spectrum of the styrylamine derivative C1 synthesized in the synthetic example 1;

FIG. 13 shows an absorption spectrum and a fluorescence spectrum of the styrylamine derivative C2 synthesized in the synthetic example 2; and

FIG. 14 shows an absorption spectrum and a fluorescence spectrum of the compound 1 synthesized in the comparative example.

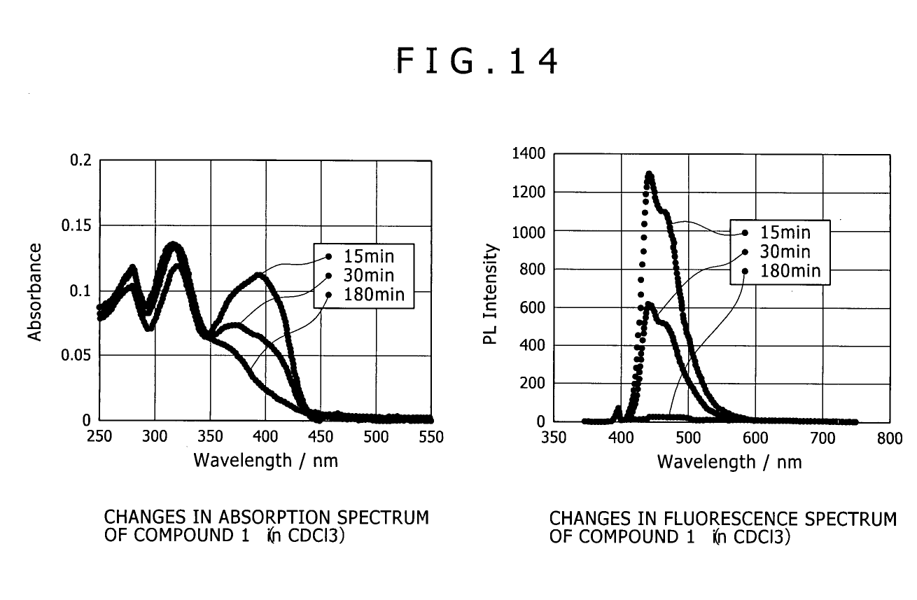

### DETAILED DESCRIPTION OF THE PREFERRED EMBODIMENTS

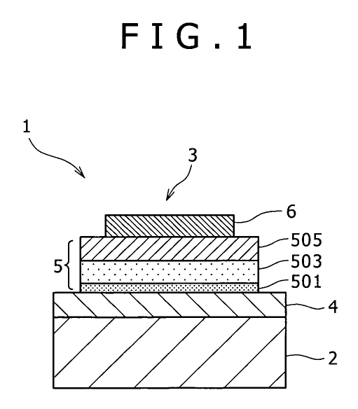

Hereinafter, exemplary embodiments of an organic electroluminescence device and a display apparatus using an organic electroluminescence device of the present invention are explained in detail with reference to the accompanying drawings. FIG. 1 is a cross sectional view showing schematically an embodiment of the organic electroluminescence device and the display apparatus with the use thereof according to the present invention.

A display apparatus 1 shown in this figure is provided with a substrate 2 and an organic electroluminescence device 3 arranged on this substrate 2. The organic electroluminescence device 3 is formed by laminating in order a lower electrode 4, organic thin film layers 5, and an upper electrode 6 on the substrate 2, and emitted light is taken out from the side of the substrate 2 or from the side of the upper electrode 6. Although the organic electroluminescence device 3 of one pixel is arranged on the substrate 2 in this figure, the display apparatus 1 is provided with a plurality of pixels, and a plurality of organic electroluminescence devices 3 are arranged for each pixel.

Next, the detailed structure of each portion forming this display apparatus 1 is explained in the order of the substrate 2, the lower electrode 4 and upper electrode 6, and the organic thin film layers 5.

The substrate 2 is formed of a glass, silicone, or plastic substrate, a thin film transistor (TFT) substrate formed with TFT, or the like. Particularly when this display apparatus 1 is a transmission type apparatus in which emitted light is taken out from the side of the substrate 2, this substrate 2 is formed of a material having light transmissibility.

The lower electrode 4 formed on the substrate 2 is used as an anode or a cathode. In the figure, a case in which the lower electrode 4 is an anode is illustrated.

This lower electrode 4 has been patterned in a suitable shape by a driving system of the display apparatus 1. For example, when the driving system of the display apparatus 1 is a simple matrix system, this lower electrode 4 is, for example, formed in a stripe shape. When the driving system of the display apparatus 1 is an active matrix system provided with TFT for every pixel, this lower electrode 4 is formed by patterning in correspondence to each pixel arranged in plurality and is similarly formed in a state that each pixel is connected to TFT arranged for each pixel via contact holes (illustration omitted) formed on inter-layer dielectric covering these TFTs.

On the other hand, the upper electrode 6 is used as a cathode when the lower electrode 4 is an anode, while it is used as an anode when the lower electrode 4 is a cathode. In the figure, a case in which the upper electrode 6 is a cathode is illustrated.

When the display apparatus 1 is of a simple matrix system, this upper electrode 6 is, for example, formed in a stripe shape crossing the stripes of the lower electrode 4, and those portions laminated crosswise serve as the organic electroluminescence device 3. When the display apparatus 1 is of an active matrix system, this upper electrode 6 is formed in a solid film shape covering the whole surface of the substrate 2 and used as an electrode common to each pixel. When the active matrix system is adopted as a driving system of the display apparatus 1, it is desirable that a top face emitting type in which emitted light is taken out from the side of the upper electrode 6 is adopted in order to secure a numerical aperture of the organic electroluminescence device 3.

The anode material forming the lower electrode 4 (or the upper electrode 6) is desired to have preferably a large work function, and for example, nickel, silver, gold, platinum, palladium, selenium, rhodium, ruthenium, iridium, rhenium, tungsten, molybdenum, chromium, tantalum, niobium, alloys or oxides of these metals, tin oxide, ITO, zinc oxide, titanium oxide, and the like are desirable.

On the other hand, the cathode material forming the upper electrode 6 (or the lower electrode 4) is desired to have preferably a small work function, and for example, magnesium, calcium, indium, lithium, aluminum, silver, and alloys of these metals are desirable.

It should be noted that, for the electrode arranged on the side from which light emitted by this organic electroluminescence device 3 is taken out, a material having light transmissibility is appropriately selected from among the above-described materials and used, and a material that transmits light equal to or more than 30% in the emission wavelength range of the organic electroluminescence device 3 is preferably used.

For example, when the display apparatus 1 is a transmission type in which emitted light is taken out from the side of the substrate 2, an anode material having light transmissibility such as ITO is used for the lower electrode 4 serving as an anode, and a cathode material having excellent reflectance such as aluminum is used for the upper electrode 6 serving as a cathode.

On the other hand, when this display apparatus 1 is a top face emitting type in which emitted light is taken out from the side of the upper electrode 6, an anode material such as chromium or silver alloy is used for the lower electrode 4 serving as an anode, and a cathode material having light transmissibility such as a compound of magnesium and silver (MgAg) is used for the upper electrode 6 serving as a cathode. Since MgAg has different light transmissibility for each wavelength, it is desired that the organic thin film layers 5 explained next are designed such that the intensity of light taken out is enhanced by optimizing the structure of a resonator according to the color of emitted light.

The organic thin film layers 5 provided between the lower electrode 4 and upper electrode 6 described above are formed by laminating in order a hole transport layer 501, a luminescent layer 503, and an electron transport layer 505 from the anode side (the side of the lower electrode 4 in the figure).

For the hole transport layer 501, a dimer, trimer, and tetramer of triphenylamine such as N,N′-di(naphthalene-1-yl) -N,N′-diphenylbenzidine (α-NPD) and N,N′-diphenyl-N,N′-bis[N-(4-methylphenyl)-N-phenyl-(4-amino phenyl)]-1,1′-biphenyl-4,4′-diamine (TPTE), and a known material such as star-burst type amine can be used as a monolayer or by laminating or mixing.

The luminescent layer 503 arranged on this hole transport layer 501 is a layer characteristic of an embodiment of the present invention and contains the styrylamine derivative explained with the use of the above general formulae 1 to 4 and the above structural formulae A1 to A53, B1 to B10, and C1 to C20 as a guest.

These styrylamine derivatives have high hole transport properties. Therefore, when its concentration in the luminescent layer is made 50% by volume or higher, light emission from the electron transport layer 505 described later is observed, thereby the luminous efficiency of the luminescent layer 503 itself is lowered. For this reason, the styrylamine derivative is introduced in the luminescent layer 503 as a guest, and the concentration of the styrylamine derivative in the luminescent layer 503 is desired to be from 1% by volume to 50% by volume, preferably from 1% by volume to 20% by volume, and more preferably from 1% by volume to 10% by volume.

In addition, known materials such as AND and DPVBi described in the related art are contained, together with the styrylamine derivative described above, as hosts in the luminescent layer 503.

Particularly when this organic electroluminescence device 3 is a blue light emitting device, a compound suitable for a blue color guest material that is selected from the range described above and from the above general formulae 1 to 4 and the above structural formulae A1 to A53, B1 to B10, and C1 to C20 is used as the styrylamine derivative introduced in the luminescent layer 503 as a guest material.

The styrylamine derivatives described above are typically obtained by the following three synthetic methods:

First Synthetic Method-1

As a first synthetic method-1 for the above-described styrylamine derivatives, the synthetic route for the styrylamine derivative represented by the structural formula A3 is shown in synthetic scheme 1 below. The synthetic scheme 1 below shows an example of synthesizing the styrylamine derivative A3 by the Suzuki coupling reaction in which a halide and a boronic acid or boronic ester are coupled using a palladium catalyst.

Formula 31

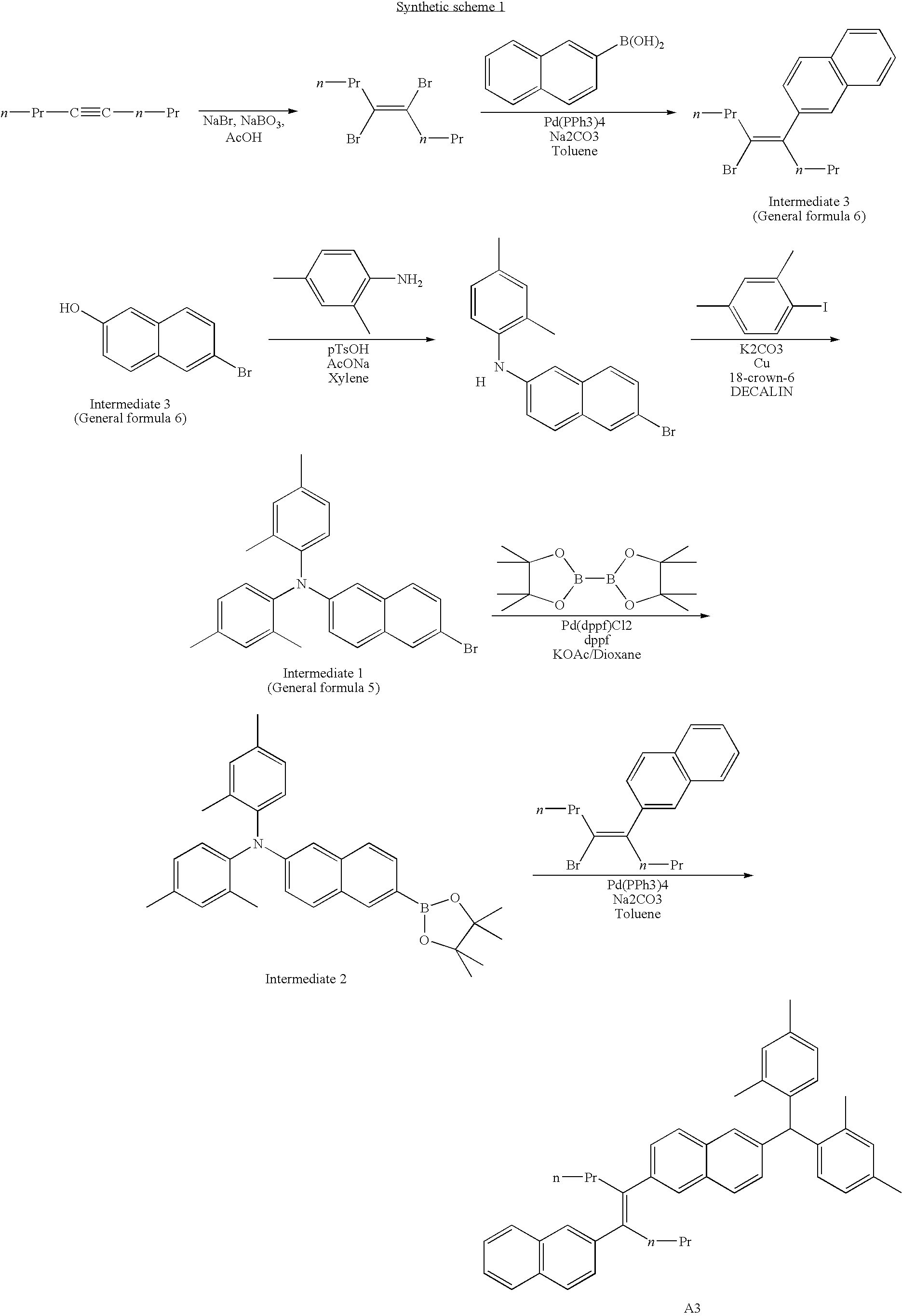

In the synthetic scheme 1, the methyl substituents are not shown.

In this synthetic scheme 1, an intermediate 1 that is an example of general formula 5 is derivatized to a boronic acid ester compound (intermediate 2). The styrylamine derivative A3 is obtained by coupling, in the presence of a palladium catalyst, this intermediate 2 to an intermediate 3 that is an example of an ethylene derivative of general formula 6 and is synthesized by another route.

First Synthetic Method-2

As a first synthetic method-2 for the styrylamine derivatives described above, the synthetic route for the styrylamine derivative represented by the structural formula A1 is shown in synthetic scheme 2 below.

Formula 32

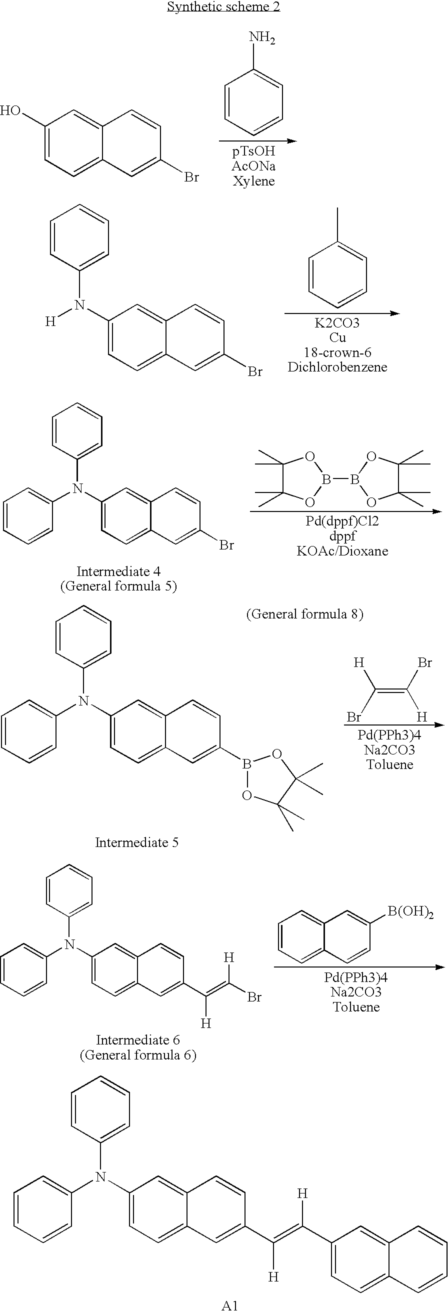

In this synthetic scheme 2, an intermediate 4 that is an example of the general formula 5 is derivatized to a boronic acid ester compound (intermediate 5). This intermediate 5 is processed to be coupled to an ethylene derivative (Br₂H₂) that is an example of general formula 8 in the presence of a palladium catalyst, thereby synthesizing an intermediate 6 that is an example of an ethylene derivative of the general formula 6. The styrylamine derivative A1 is obtained by coupling reaction of this intermediate 6 in the presence of a palladium catalyst.

Second Synthetic Method

As a second synthetic method for the styrylamine derivatives, the synthetic route for the styrylamine derivative represented by the structural formula C17 is shown in synthetic scheme 3 below. The synthetic scheme 3 below shows an example of synthesizing the compound C17 by the McMurry reaction that allows a carbonyl compound to be coupled by the use of a low valence titanium. By using the McMurry reaction, it is possible to decrease the number of synthetic steps for a compound that is highly symmetric with respect to a double bond portion.

Formula 33

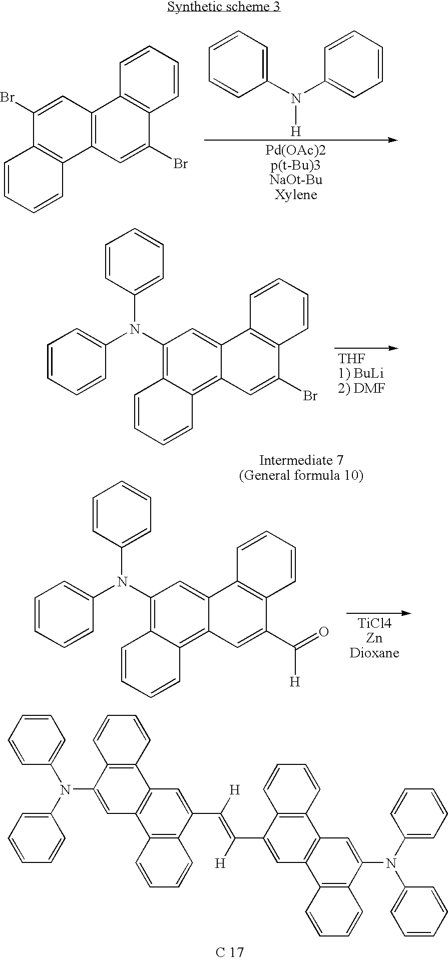

In this synthetic scheme 3, an intermediate 7 that is an example of general formula 10 is synthesized, and the styrylamine derivative C17 is obtained by coupling this intermediate 7 in the presence of a low valence titanium.

Third Synthetic Method

As a third synthetic method for the above-described styrylamine derivatives, the synthetic route for the styrylamine derivative represented by the structural formula A2 is shown in synthetic scheme 4 below. The synthetic scheme 4 below shows an example of synthesizing the compound A2 by the Wittig reaction or the Horner-Emmons reaction in which a carbonyl compound and a phosphonium salt or a phosphite ester are coupled in the presence of a base.

Formula 34

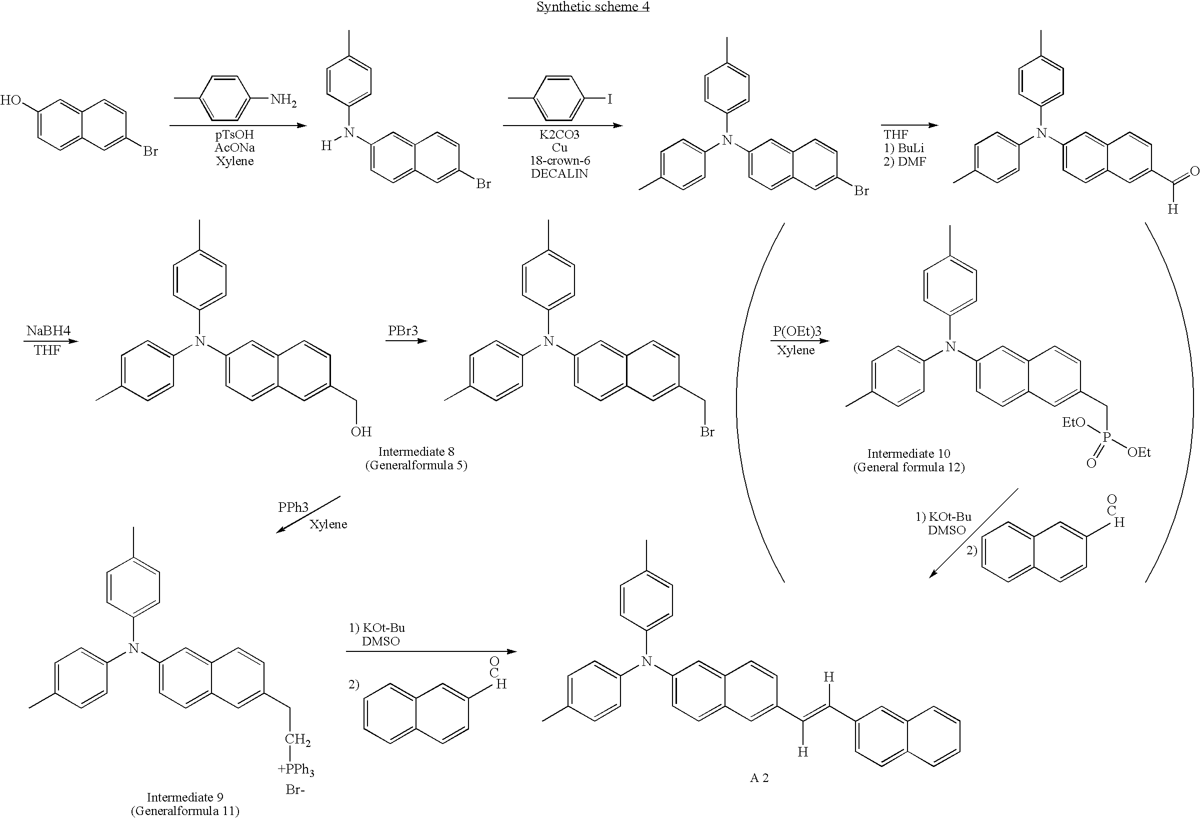

In the synthetic scheme 4, the methyl substituents are not shown.

In this synthetic scheme 4, an intermediate 9 that is an example of general formula 11 is synthesized via an intermediate 8 that is an example of the general formula 5. The styrylamine derivative A2 is obtained by coupling this intermediate 9 to the carbonyl compound (Wittig reaction).

Alternatively, an intermediate 10 that is an example of general formula 12 is synthesized via the intermediate 8 as shown in the parenthesis in the synthetic scheme 4. The styrylamine derivative A2 is obtained by coupling this intermediate 10 to the carbonyl compound (Horner-Emmons reaction).

It should be noted that the above synthetic methods are merely typical examples and the synthetic method for the styrylamine derivatives of the present invention are not limited to the above three examples. Since isomerization of a double bond portion is easy to take place by light and heat during the synthetic process of the styrylamine derivatives of the present invention, it is desirable to employ a synthetic route in which a reaction to form the double bond portion is postponed until as later as possible.

For the electron transport layer 505 arranged on the luminescent layer 503, known materials such as Tris-(8-hydroxy-quinolinato)-aluminum (Alq3) and derivatives of oxydiazole, triazole, benzimidazole, and silole can be used.

Although illustration other than that of the structure explained in the foregoing is omitted here, a hole injection layer may be inserted between the lower electrode 4 that serves as an anode and the hole transport layer 501. For the hole injection layer, conductive polymer such as polyphenylenevinylene (PPV) and known materials such as copper phthalocyanine, star-burst type amine, and dimer, trimer, and tetramer of triphenylamine can be used as a monolayer or by laminating or mixing with each other. The efficiency of hole injection is enhanced by inserting such a hole injection layer, which is more desirable.

Although illustration is omitted here, an electron injection layer may be further inserted between the electron transport layer 505 and the cathode 6 (upper electrode). For the electron injection layer, an alkali metal oxide such as lithium oxide, lithium fluoride, cesium iodide, or strontium fluoride, an alkali metal halide, an alkaline-earth oxide, and an alkaline-earth halide can be used. The efficiency of electron injection is enhanced by inserting such an electron injection layer, which is more desirable. Further, in place of the hole transport layer 501, a hole transfer injection layer may be arranged between the lower electrode 4 that serves as an anode and the luminescent layer 503.

Although illustration is omitted here, an electron injection layer may be further inserted between the electron transport layer 505 and the cathode 6 (upper electrode). For the electron injection layer, an alkali metal oxide such as lithium oxide, lithium fluoride, cesium iodide, or strontium fluoride, an alkali metal fluoride, an alkaline-earth oxide, and an alkaline-earth fluoride can be used. The efficiency of electron injection is enhanced by inserting such an electron injection layer, which is more desirable.

In order to form the organic thin film layers 5 having a structure in which the materials such as the above are laminated, a known method such as vacuum deposition or spin coating may be applied.

Although illustration is omitted here, it is desirable in the display apparatus 1 provided with the organic electroluminescence device 3 in such a structure to form a sealing film made of magnesium fluoride, silicon nitride (SiNx), and the like on the substrate 2 such that the organic electroluminescence device 3 is covered or to cover the organic electroluminescence device 3 with a sealing can and then purge its hollow portion with a dry inert gas or evacuate in order to prevent the organic electroluminescence device 3 from being deteriorated by moisture or oxygen in the air.

Although illustration is omitted here, in the display apparatus 1 provided with the organic electroluminescence device 3 in such a structure, color display may also be performed by arranging other color light emitting organic electroluminescence devices together with this organic electroluminescence device 3 for each pixel, forming one pixel with these plural pixels as sub-pixels, and arranging each pixel consisting of a set of these plural pixels in plurality on the substrate 2. For example, when the organic electroluminescence device 3 that contains the styrylamine derivative described above in the luminescent layer is used as a blue light emitting device, a red light emitting device and a green light emitting device are arranged with the blue light emitting device for each pixel, one pixel is formed of these three pixels as sub-pixels, and each pixel consisting of a set of these three pixels is arranged in plurality on the substrate 2, thereby full color display may be performed.

In the organic electroluminescence device 3 having the structure explained above, it becomes possible to obtain luminescence having high luminous efficiency, low attenuation factor, and high reliability by allowing the styrylamine derivative shown in the general formula 1 to be contained in the luminescent layer 503.

Particularly, luminescence in a blue wavelength range having excellent color purity can be obtained by allowing a specific styrylamine derivative among the styrylamine derivatives shown in the general formula 1 to be contained in the luminescent layer 503. The display apparatus 1 provided with such an organic electroluminescence device 3 makes it possible to perform full color display with high color expressivity by combining this organic electroluminescence device 3 with a red light emitting organic electroluminescence device and a green light emitting organic electroluminescence device.

In the embodiment described above, a case in which the styrylamine derivative specific to the present invention was used for the luminescent layer forming the organic thin film layers was exemplified. However, even when the styrylamine derivative having the structure described above is used in an organic thin film layer other than the luminescent layer, it is possible to suppress deterioration of the organic thin film layer and thus extend the life of the organic electroluminescence device because the styrylamine derivative is excellent in chemical stability. Further, since this styrylamine derivative is excellent in hole transport property, it can be used for a hole transport layer or a hole injection layer between the luminescent layer and an anode, thereby improving durability of the organic thin film layer as well as luminous efficiency due to an enhancement of efficiency of hole injection to the luminescent layer.

### EXAMPLES

Hereinafter, specific examples of the present invention and a comparative example are explained. Further, synthetic examples of the styrylamine derivatives used in the present invention are also explained.

### Example 1

A glass substrate (ITO substrate) having a transparent ITO electrode with a film thickness of 190 nm was ultrasonically washed with a neutral detergent, acetone, and ethanol. After drying, this ITO substrate was subjected to UV/ozone treatment for 10 min. Then, this ITO substrate was fixed on a substrate holder of a vapor deposition apparatus, followed by evacuation of the deposition chamber to 1.4×10⁻⁴ Pa.

First, N,N′-di(naphthalene-1-yl)-N,N′-diphenylbenzidine (αNPD) was deposited on the transparent ITO electrode in a thickness of 65 mm at a deposition rate of 0.2 nm/sec to form a hole injection transport layer. Next, with the use of 9,10-di(2-naphthyl)anthracene (AND) as a host and the styrylamine derivative shown by the structural formula C1 (corresponding to the structural formula 1) as a guest, these were co-deposited in a thickness of 35 mm each at a deposition rate of 0.2 nm/sec using different deposition sources to form a luminescent layer having a guest concentration of 2.5% by volume. Then, Tris-(8-hydroxy-quinolinato)-aluminum (Alq3) was deposited in a thickness of 15 nm at a deposition rate of 0.2 nm/sec to form an electron transport layer. On this layer, lithium fluoride (LiF) was deposited in a thickness of 0.1 mm, and further magnesium and silver were co-deposited (atomic ratio 95:5) in a thickness of 70 nm at a deposition rate of about 0.4 nm/sec to form a cathode. Thus, an organic electroluminescence device was produced.

### Examples 2 And 3

Organic electroluminescence devices were produced in the same manner as in the example 1 except that the concentrations of the guest consisting of the styrylamine derivative of the structural formula C1 in the luminescent layer were 5 and 10% by volume, respectively, in the production procedures of the organic electroluminescence device described in the example 1.

### Example 4

An organic electroluminescence device was produced in the same manner as in the example 1 except that the styrylamine derivative of the structural formula C2 (2.5% by volume) was used as the guest in the luminescent layer in the production procedures of the organic electroluminescence device described in the example 1.

### Example 5

An organic electroluminescence device was produced in the same manner as in the example 1 except that the styrylamine derivative of the structural formula C6 (corresponding to the structural formula 3) (2.5% by volume) was used as the guest in the luminescent layer in the production procedures of the organic electroluminescence device described in the example 1.

### Comparative Example

An organic electroluminescence device was produced in the same manner as in the example 1 except that BCzVBi shown in Non-patent Document 2 was used as the guest material in place of the guest consisting of the styrylamine derivative of the structural formula C1 in the luminescent layer in the production procedures of the organic electroluminescence device described in the example 1. The concentration of the guest was 5% by volume.

### EVALUATION RESULTS

Evaluation of the organic electroluminescence devices produced in each example and comparative example was carried out by measuring luminescence characteristics when these devices were driven by DC at 25.0 mA/cm² and half-life of brightness when driven continuously (duty 50%) at 60.0 mA/cm² in nitrogen atmosphere. These results are shown in Table I below.

TABLE I

| | | | | | | Luminescence | Power | |
|---|---|---|---|---|---|---|---|---|
| | Guest | Brightness | | ELmax | Voltage | Efficiency | Efficiency | Half-life |
| | concentration | [Cd/m²] | Chromaticity | [nm] | [V] | [Cd/A] | [lm/W] | [hrs] |
| Example 1 | SF(C1): 2.5% | 1580 | (0.139, 0.201) | 461 | 6.77 | 6.32 | 2.10 | 1710 |
| Example 2 | SF(C1): 5.0% | 1920 | (0.138, 0.225) | 463 | 6.35 | 7.44 | 2.67 | 1740 |
| Example 3 | SF(C1): 10.0% | 1270 | (0.149, 0.265) | 466 | 5.51 | 6.36 | 2.51 | 1470 |
| Example 4 | SF(C4): 2.5% | 2010 | (0.135, 0.230) | 469 | 6.20 | 8.05 | 2.79 | 2270 |
| Example 5 | SF(C6): 2.5% | 2130 | (0.140, 0.232) | 464 | 7.18 | 8.52 | 3.72 | 1900 |
| Comparative | BCzVBi: 5.0% | 845 | (0.170, 0.292) | 480 | 6.45 | 3.38 | 1.18 | 630 |
| example | | | | | | | | |

*SF refers to structural formula.

In the organic electroluminescence device of the example 1 in which a luminescent layer was formed by using the styrylamine derivative having the structural formula C1 of the present invention as a guest, a blue light emission having brightness of 1580 Cd/cm² was confirmed by DC driving at a current density of 25.0 mA/cm² as shown in Table I. The driving voltage, the luminescence efficiency, and the power efficiency were 6.77 V, 6.32 Cd/A, 2.10 m/W, respectively. The half-life at a current density of 60 mA/cm² in nitrogen atmosphere was 1710 hours. A high purity blue color with chromaticity (0.139, 0.201) was also obtained.

In the organic electroluminescence devices of the examples 2 and 3 in which luminescent layers were formed by using the same styrylamine derivative having the structural formula C1, their chromaticity lied in a range of blue color, though shifted toward green region in accordance with increasing concentration of C1. Their luminescence efficiencies were higher than 6.32 Cd/A, and half-lives were at least 1470 hours.

In the organic electroluminescence devices of the examples 4 and 5 in which luminescent layers were formed by using the styrylamine derivatives of the present invention having the structural formulae C2 and C6 as a guest, respectively, blue light emission having brightness still higher than 2000 Cd/m² was confirmed for both devices by DC driving at a current density of 25.0 mA/cm². Their luminescence efficiencies and half-lives were still better than those of C1.

In contrast, the organic electroluminescence device of the comparative example in which BCzVi was used as a guest material for the luminescent layer showed low brightness of 845 as well as low luminescence efficiency of 3.38 Cd/A. Further, not only was the chromaticity (0.170, 0.292) inferior but also the half-life was as short as 630 hours. From these results, it was confirmed that improvement of luminescence efficiency, attainment of high color purity, and prolongation of life of an organic electroluminescence device could be achieved by using the styrylamine derivatives of the present invention.

### Synthetic Example 1

The styrylamine derivative C1 shown above was synthesized according to synthetic scheme 5 shown below.

Formula 35

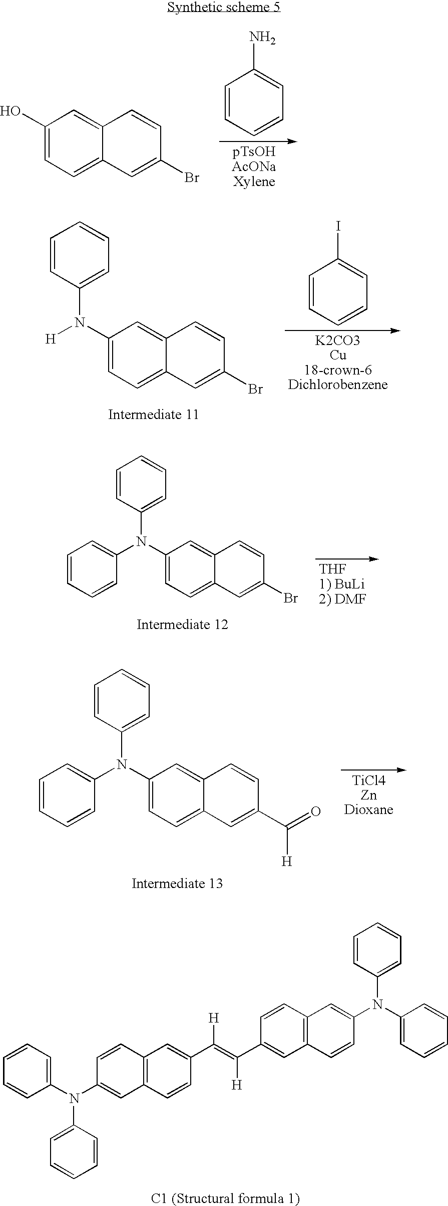

First, a stirring bar, 75.9 g (0.34 mol) of 6-bromo-2-naphthol, 144 ml (1.58 mol) of aniline, 13.3 g (0.07 mol) of p-toluenesulfonic acid monohydrate, and 114 ml of xylene were added into a 300 ml receiving flask, and the air in the reaction vessel was replaced with argon, followed by reaction for 15 hours at 120 degrees C. while mixing with a stirrer. During the reaction, water was removed by using a Dean-Stark apparatus. After the reaction solution was left standing to cool, 17.1 g (0.21 mol) of sodium acetate and 460 ml of ethanol were added, refluxed for a while, and then cooled. Precipitated crystal was collected by filtration and washed with 250 ml of ethanol to afford 88 g (crude) of an intermediate 11 as a white crystal.

Next, 70.0 g (0.23 mole) of the intermediate 11, 116.3 g (0.57 mol) of iodobenzene, 143 g (1.03 mol) of potassium carbonate, 9.4 g (0.15 mol) of copper powder, 8.7 g (0.032 mol) of 18-Crown-6, and 235 ml of o-dichlorobenzene were added into a 300 ml receiving flask and refluxed for 6 hours under nitrogen atmosphere. The reaction solution was filtered on Celite and purified by chromatography to afford 56 g of an intermediate 12 (corresponding to the general formula 5) as a white crystal. The yield was 65%.

Then, 55.9 g (0.15 mol) of the intermediate 12 and 450 ml of anhydrous THF were added into a 500 ml three-neck flask, and the air in the reaction vessel was replaced with argon. The reaction vessel was then cooled to −50 to −45 degrees C. with calcium chloride and dry ice, and 115 ml (0.18 mol) of 1.58 mol/l BuLi was added. After stirring for one hour at the same temperature, a solution of 21 ml of DMF diluted with 90 ml of anhydrous THF was dropped over 5 min. After dropping of the solution, the mixture was stirred for 3.5 hours, followed by partitioning by adding 60 ml of a dilute hydrochloric acid solution and 600 ml of toluene. The organic layer was separated, dried over anhydrous magnesium sulfate, and concentrated in vacuo. The obtained oily substance was crystallized by adding hexane and recrystallized after filtration to afford 36.0 g of an intermediate 13 (corresponding to the general formula 10) as a yellow crystal. The yield was 74.2%.

Subsequently, 16.0 g (0.05 mol) of the intermediate 13, 495 ml of anhydrous dioxane, and 9.8 g (0.15 mol) of zinc powder were added into a one-liter three-neck flask, and 11.0 ml (0.10 mol) of titanium tetrachloride was dropped while cooling the reaction vessel in an ice bath, followed by refluxing for 15 hours under argon atmosphere. To the reaction solution, an aqueous solution of 10% potassium carbonate and toluene were added and partitioned. The organic layer was separated, dried over anhydrous magnesium sulfate, and concentrated in vacuo. Crude product was purified twice by column chromatography to afford 4.3 g of the styrylamine derivative represented by C1 as a yellow crystal. The yield was 28%.

### Synthetic Example 2

The styrylamine derivative C2 shown above was synthesized according to synthetic scheme 6 below.

Formula 36 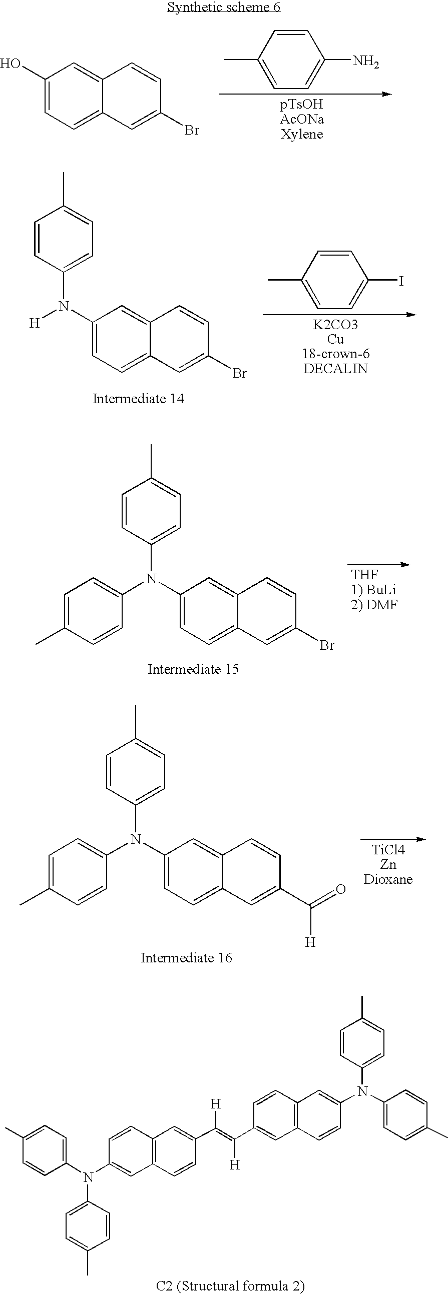
In the synthetic scheme 6, the methyl substituents are not shown.

First, a stirring bar, 125 g (0.56 mol) of 6-bromo-2-naphthol, 224 g (2.11 mol) of p-toluidine, 13.3 g (0.11 mol) of p-toluenesulfonic acid monohydrate, and 200 ml of xylene were added into a 300 ml receiving flask, and the air in the reaction vessel was replaced with argon, followed by reaction for 15 hours at 120 degrees C. while mixing with a stirrer. During the reaction, water was removed by using a Dean-Stark apparatus. After the reaction solution was left standing to cool, 28.2 g (0.34 mol) of sodium acetate and 760 ml of ethanol were added, refluxed for a while, and then cooled. Precipitated crystal was collected by filtration and washed with ethanol to afford 154.4 g of an intermediate 14 as a white crystal. The yield was 88%.

Next, 140 g (0.45 mole) of the intermediate 14, 269 g (1.96 mol) of potassium carbonate, 18 g (0.28 mol) of copper powder, 16.7 g (0.063 mol) of 18-Crown-6, and 2 liters of Decalin were added into a three-liter reaction vessel and refluxed for 6 hours under nitrogen atmosphere. To the reaction solution, 2 liters of THF was added, filtered on Celite, and purified by chromatography to afford 109 g of an intermediate 15 (corresponding to the general formula 5) as a white crystal. The yield was 60%.

Then, 78.0 g (0.19 mol) of the intermediate 15 and 660 ml of anhydrous THF were added into a one-liter three-neck flask, and the inside of the reaction vessel was replaced with argon. The reaction vessel was then cooled to −50 to −45 degrees C. with calcium chloride and dry ice, and 149 ml (0.24 mol) of 1.58 mol/l BuLi was added. After stirring for one hour at the same temperature, a solution of 27 ml of DMF diluted with 120 ml of anhydrous THF was dropped over 5 min. After dropping of the solution, the mixture was stirred for 2 hours, followed by partitioning by adding 80 ml of water and 800 ml of toluene. The organic layer was separated, dried over anhydrous magnesium sulfate, and concentrated in vacuo. The obtained oily substance was purified by chromatography to afford 49 g of an intermediate 16 (corresponding to the general formula 10) as a crystal. The yield was 73%.

Subsequently, 16.48 g (0.14 mol) of the intermediate 16, 900 ml of anhydrous dioxane, and 28.0 g (0.43 mol) of zinc powder were added into a two-liter three-neck flask, and 24 ml (0.22 mol) of titanium tetrachloride was dropped while cooling the reaction vessel in an ice bath, followed by refluxing for 15 hours under argon atmosphere. To the reaction solution, an aqueous solution of 10% potassium carbonate and toluene were added and partitioned. The organic layer was separated, dried over anhydrous magnesium sulfate, and concentrated in vacuo. Crude product was purified twice by column chromatography to afford 8.2 g of the styrylamine derivative represented by C2 as a yellow crystal. The yield was 9%.

### Comparative Example

The compound 1 was synthesized as a comparative example according to synthetic scheme 7 below.

Formula 37

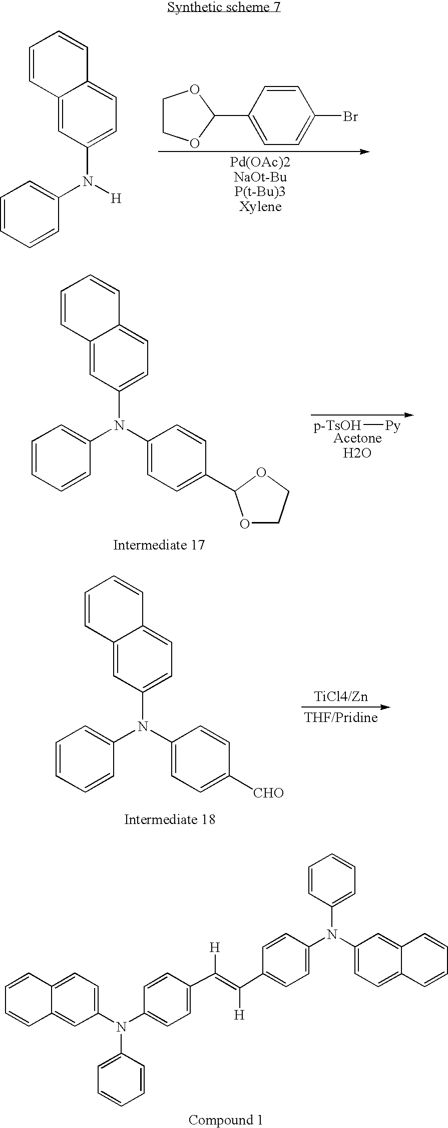

First, 9.160 g (0.040 mol) of 2-(4-bromophenyl)-1,3-dioxolane, 8.770 g (0.04 mol) of N-phenyl-2-naphthylamine, 0.180 g (0.8 mmol) of palladium acetate (II) , 4.610 g (0.048 mol) of sodium t-butoxide, and 700 ml of xylene were added into a one-liter three-neck flask, 32 ml (3.2 mmol) of a solution of 0.1 mol/l tri-t-butylphosphine in xylene was slowly dropped while mixing with a stirring bar, and the air in the reaction vessel was replaced with nitrogen, 10 followed by reaction for 7.5 hours at 110 degrees C. Then, treatment by partitioning and purification by column chromatography three times were carried out to afford 10.23 g of an intermediate 17. The yield was 70%.

Next, 10.23 g of the intermediate 17, 600 ml of acetone, 140 ml of water, and 0.754 g (0.003 mol) of pyridinium salt of p-toluenesulfonic acid were added into a one-liter three-neck flask and stirred for 30 min at room temperature and for 3 hours at 50 degrees C. with a stirring bar. Then, treatment by partitioning and purification by column chromatography twice were carried out to afford ca. 8.07 g of an intermediate 18. The yield was 92%.

Subsequently, 0.91 g (0.014 mol) of zinc and 77 ml of THF were added into a 500 ml three-neck flask, and 0.78 ml (0.007 mol) of titanium tetrachloride and 3.8 ml of pyridine were dropped and mixed with a stirring bar while the reaction vessel was cooled in an ice bath. Then, 1.03 g (0.003 mole) of the intermediate 18 dissolved in 33 ml of THF was dropped over 30 min, and the reaction solution was changed to nitrogen atmosphere. After reaction for 20 min at room temperature and for 5 hours at 60 degrees C., an aqueous solution of 10% potassium carbonate was added, treated by partitioning, and purified by column chromatography five times to afford 0.346 g (0.56 mmol) of the compound 1. The yield was 19%.

### Evaluation Results 1

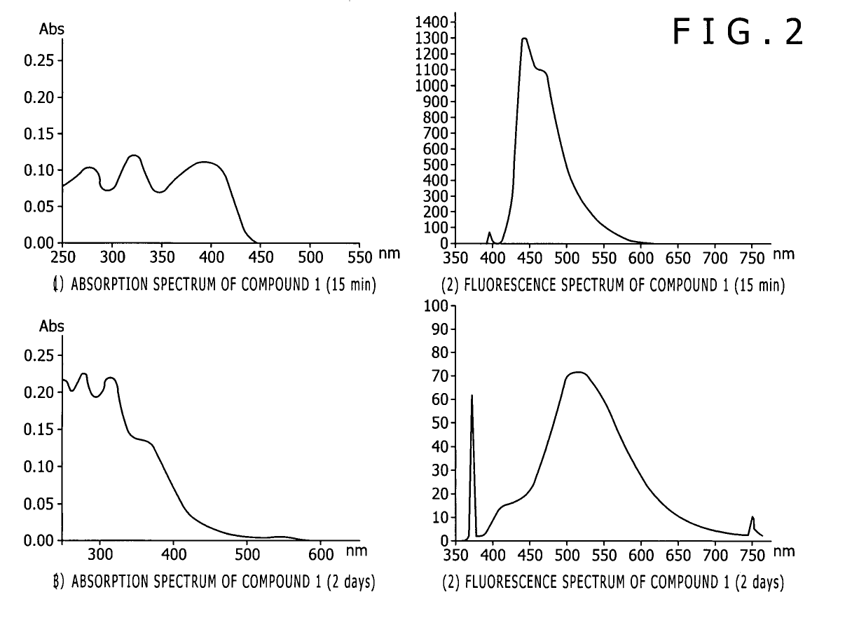

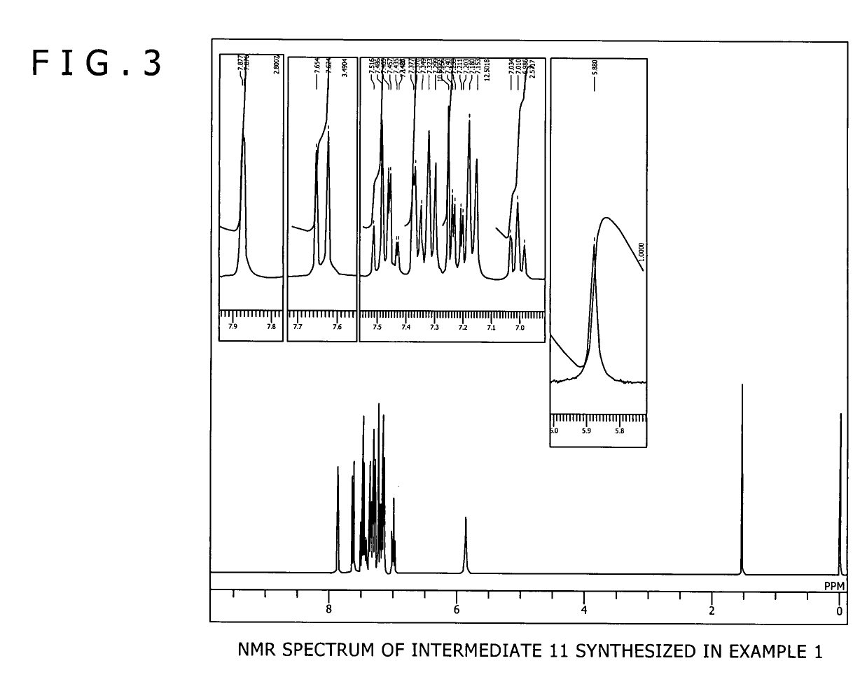

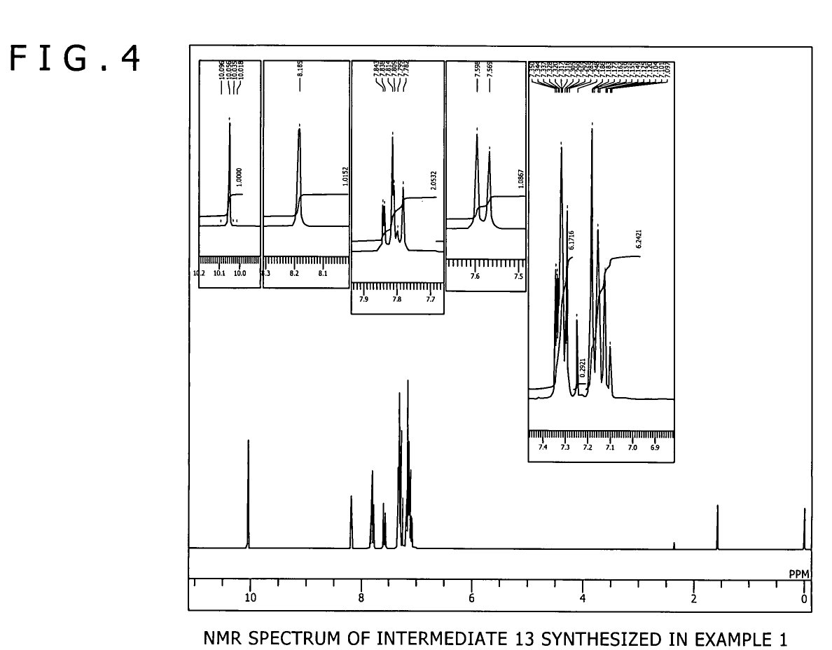

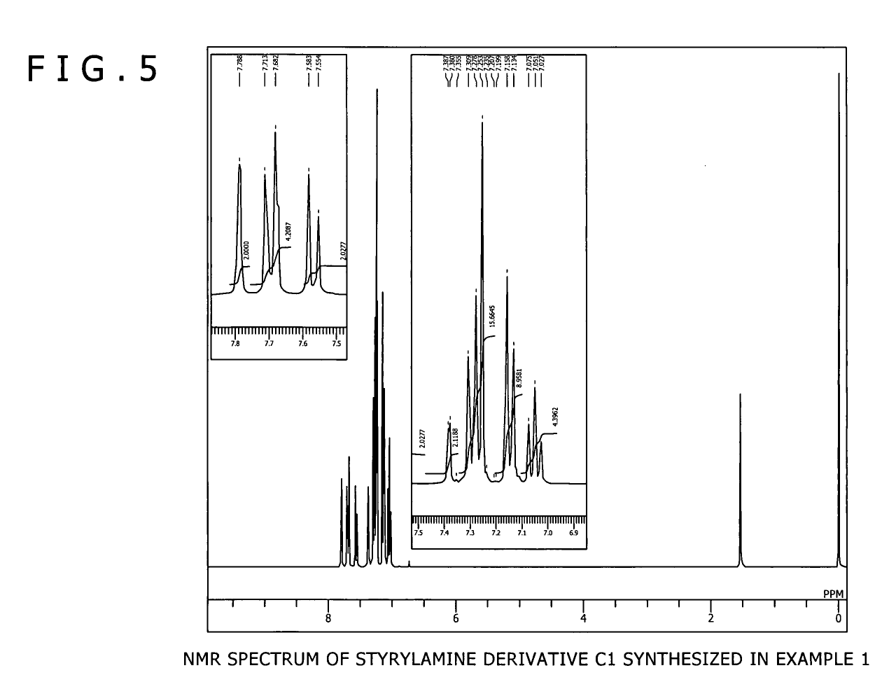

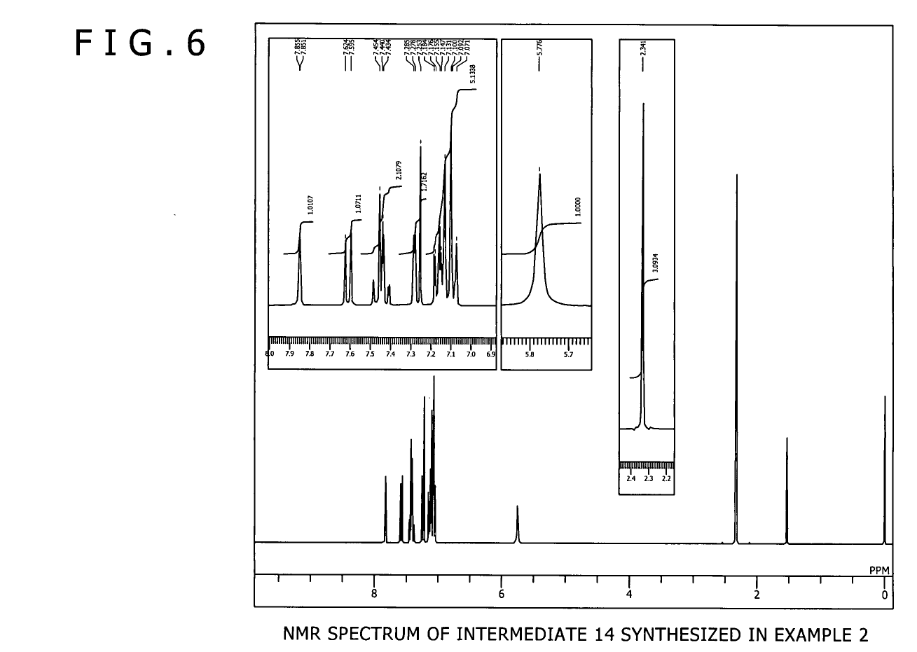

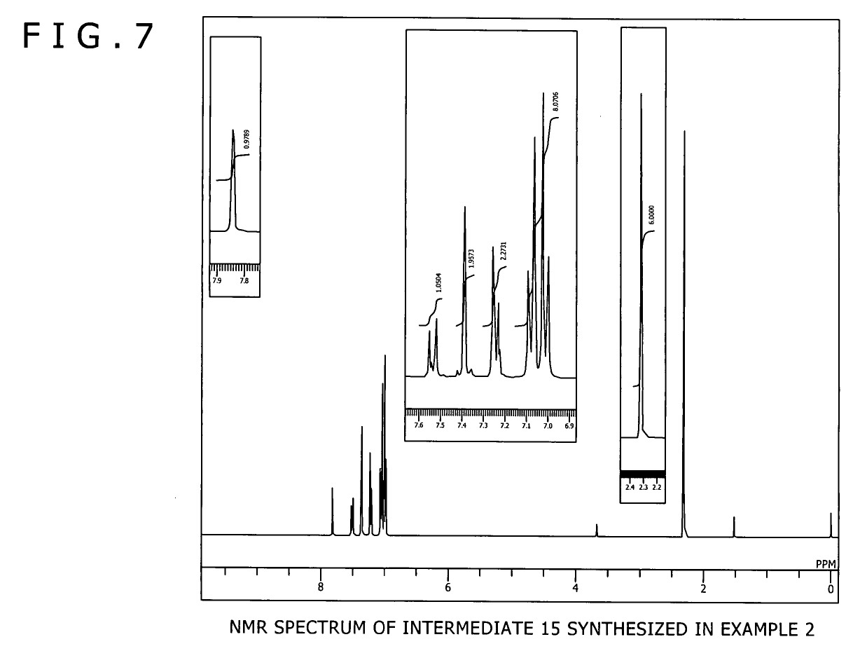

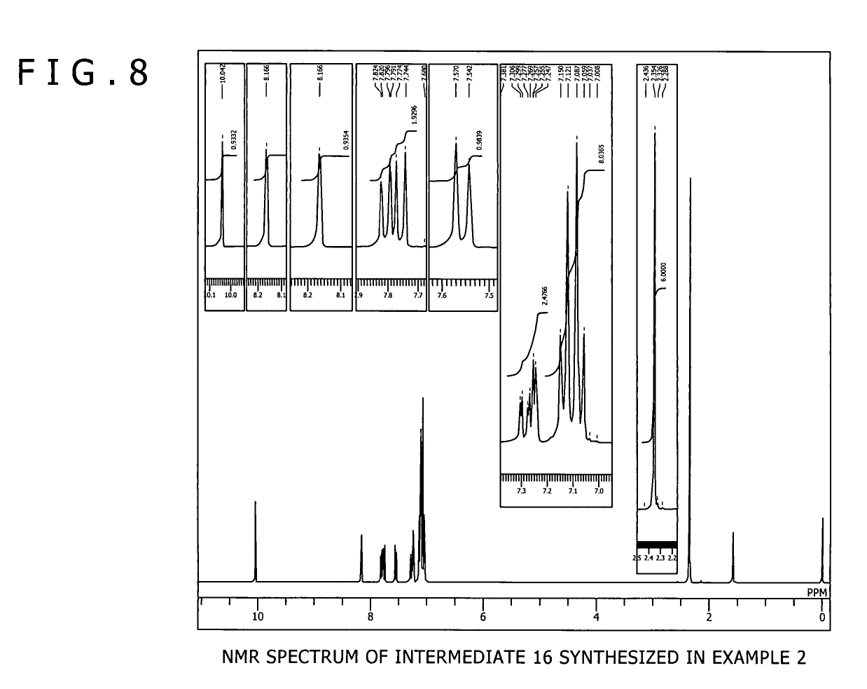

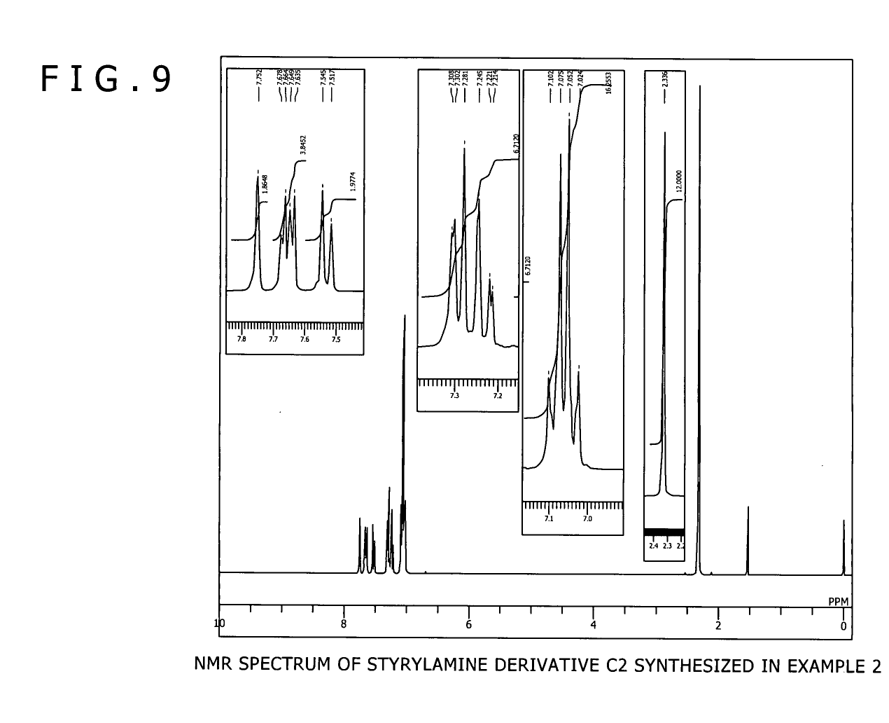

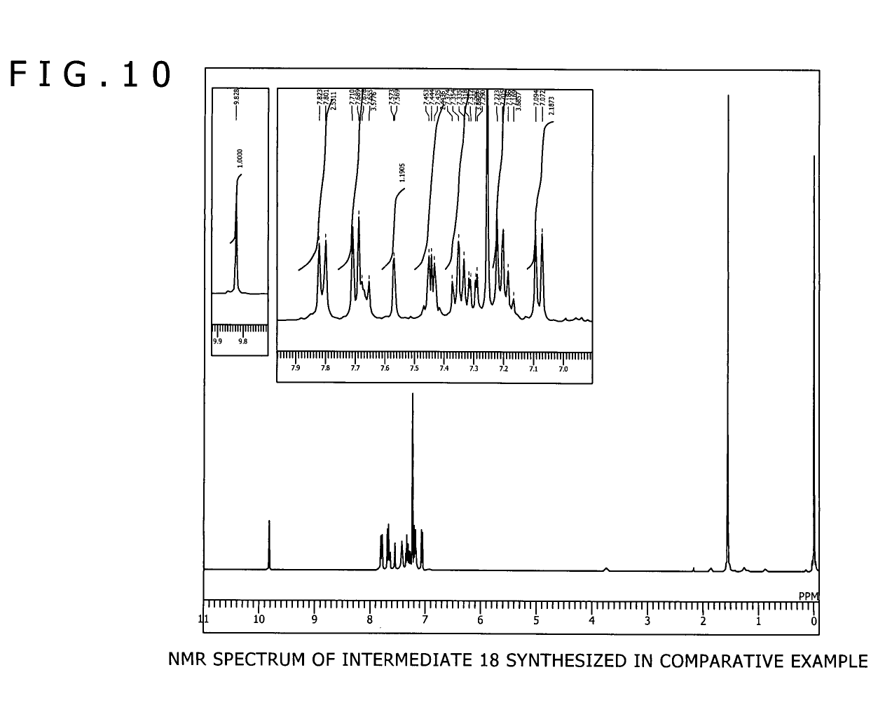

The NMR spectra of each of the intermediates, the styrylamine derivatives, and the compound 1 shown in the synthetic examples 1 and 2 and the comparative example are shown in FIGS. 2 to 10.

From these NMR spectra, it was confirmed that each of the intermediates, the styrylamine derivatives, and the compound 1 shown in the synthetic schemes 5 to 7 was synthesized in each of the synthetic processes.

### Evaluation Results 2

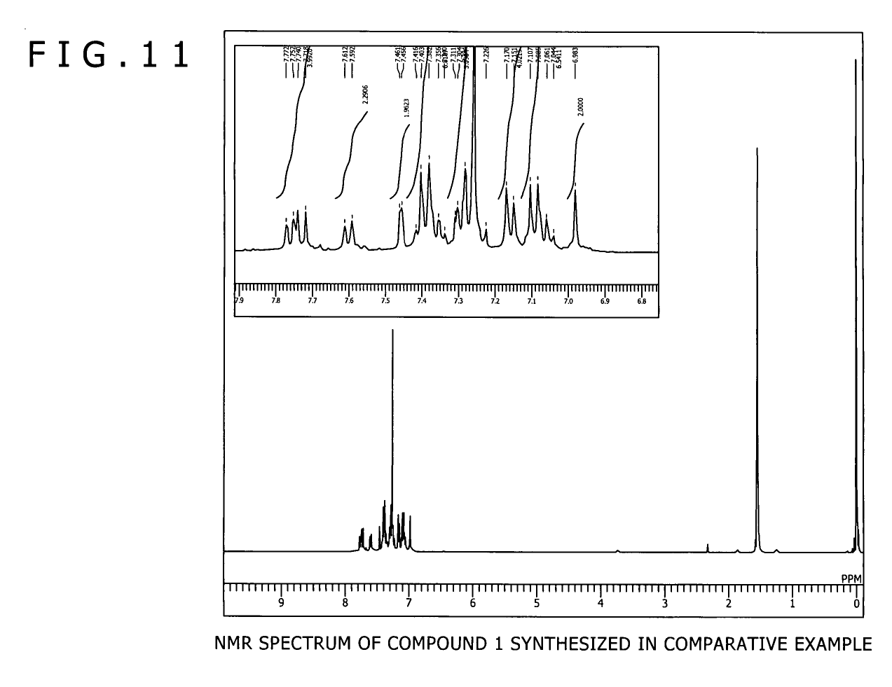

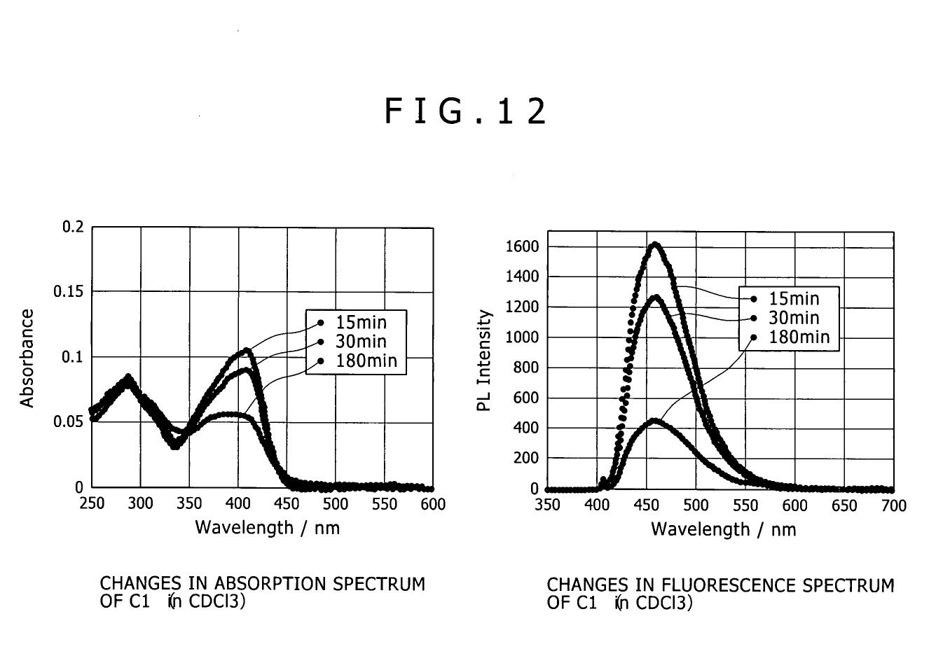

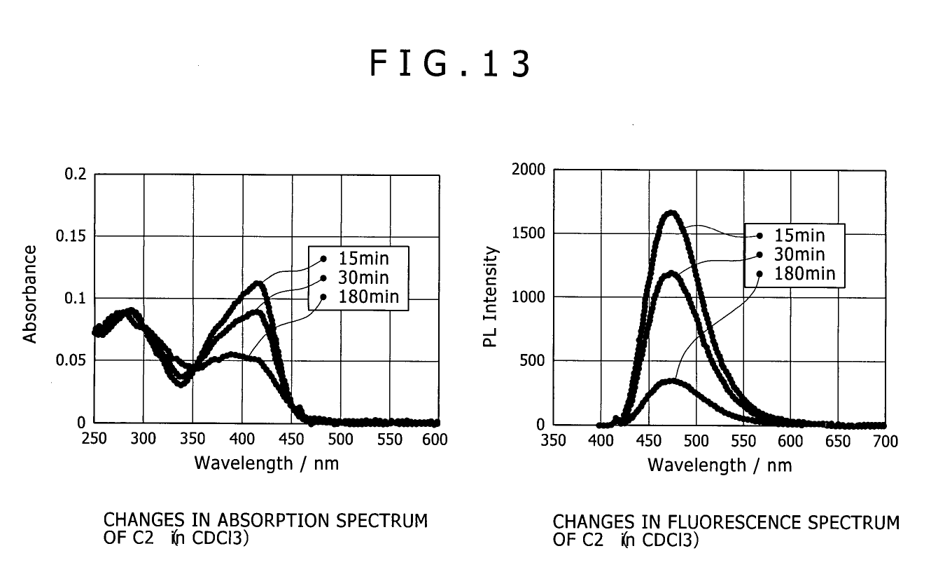

The styrylamine derivatives synthesized in the synthetic examples 1 and 2 and the compound 1 synthesized in the comparative example were dissolved in the deuterated chloroform solvent produced by Aldrich (Product No. 22578-9) and adjusted so that their absorbance peaks at the longest wavelengths exhibit approximately an absorbance of 0.1, followed by measurements of their absorption spectra and fluorescence spectra after 15, 30, and 180 min, respectively. The absorption spectra and fluorescence spectra of each synthetic compound are shown in FIGS. 11 to 13. The measurements of the absorption spectra and fluorescence spectra were carried out with Hitachi Model U3300 spectrophotometer and Hitachi Model F4500 spectrofluorometer, respectively.

When the absorption spectrum of the compound 1 of the comparative example after 15 min was compared with that after 180 min by focusing attention on the peak at the longest wavelength in the absorption spectrum, the intensity of the peak at 396 nm decreased to 24%, while the styrylamine derivative C1 of the example 1 retained an intensity of 53% at 408 nm, and the styrylamine derivative C2 of the example 2 retained an intensity of 43% at 417 nm.

On the other hand, in fluorescence spectrum, attention was focused on the peak of a fluorescence spectrum obtained by excitation of the peak at the longest wavelength in the absorption spectrum. When the spectrum of the compound 1 of the comparative example after 15 min was compared with that after 180 min, the fluorescence intensity of the peak at 444 nm decreased to 1%. In contrast to this result, the fluorescence spectrum of the styrylamine derivative C1 of the synthetic example 1 resulted in retention of a fluorescence intensity of 28% at 461 nm, and the fluorescence spectrum of the styrylamine derivative C2 of the synthetic example 2 resulted in retention of a fluorescence intensity of 21% at 474 nm.

As described above, the novel styrylamine derivatives of the present invention were confirmed to be compounds that were suppressed in deterioration even in deuterated chloroform not containing a stabilizer.

### Evaluation Results 3

The styrylamine derivatives C1 and C2 synthesized in the synthetic examples 1 and 2, respectively, and the compound 1 synthesized in the comparative example were dissolved in toluene, respectively, and subjected to thin layer chromatography (TLC) with double development. For the TLC plate, 25TLC aluminium sheet (adsorbent: silica gel 60F254) produced by Merck & Co., Inc. was used, and a mixed solvent of toluene and cyclohexane (1:3) was used as the developing solvent.

The styrylamine derivatives C1 and C2 synthesized in the synthetic examples 1 and 2, respectively, did not reveal any spot other than C1 and C2 at the second development, thus confirming no deterioration. In contrast, the compound 1 of the comparative example revealed tailing even at the second development, thereby confirming deterioration.

It should be understood by those skilled in the art that various modifications, combinations, sub-combinations and alterations may occur depending on design requirements and other factors insofar as they are within the scope of the appended claims or the equivalents thereof.

What is claimed is:

1. An organic electroluminescence device having organic thin film layers provided between an anode and a cathode and including at least a luminescent layer, comprising:
a styrylamine derivative represented by general formula 1 below in any one of the organic thin film layers.
Formula 1 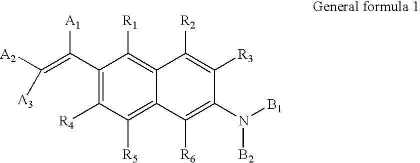
(wherein
R₁ to R₆ each independently represents
hydrogen, halogen, hydroxyl, cyano, nitro, amino,
a saturated or unsaturated hydrocarbon group,
a saturated or unsaturated hydrocarbon oxy group,
a substituted or unsubstituted aryl group,
a substituted or unsubstituted aryloxy group,
a substituted or unsubstituted heterocyclic group,
a saturated or unsaturated hydrocarbon amino group, or
a substituted or unsubstituted arylamino group,
where adjacent groups other than hydrogen, halogen, cyano, and nitro may join to each other to form a saturated or unsaturated carbon ring, and
A₁ to A_{3,} B_{1,} and B₂ each independently represents hydrogen,
a saturated or unsaturated hydrocarbon group,
a substituted or unsubstituted aryl group, or
a substituted or unsubstituted heterocyclic group,
where adjacent groups may join to each other to form a saturated or unsaturated carbon ring.)

2. The organic electroluminescence device according to claim 1, wherein at least one of A₁ to A₃ in the general formula 1 is represented by general formula 2 below.
Formula 2 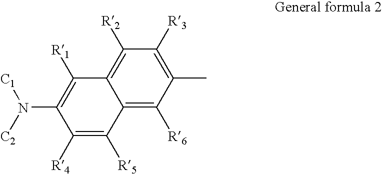
(wherein
R′₁ to R′₆ each independently represents
hydrogen, halogen, hydroxyl, cyano, nitro, amino,
a saturated or unsaturated hydrocarbon group,
a saturated or unsaturated hydrocarbon oxy group,
a substituted or unsubstituted aryl group,
a substituted or unsubstituted aryloxy group,
a substituted or unsubstituted heterocyclic group,
a saturated or unsaturated hydrocarbon amino group, or
a substituted or unsubstituted arylamino group,
where adjacent groups other than hydrogen, halogen, cyano, and nitro may join to each other to form a saturated or unsaturated carbon ring, and
C₁ and C₂ each independently represents
hydrogen,
a saturated or unsaturated hydrocarbon group,
a substituted or unsubstituted aryl group, or
a substituted or unsubstituted heterocyclic group,
where adjacent groups may join to each other to form a saturated or unsaturated carbon ring.)

3. The organic electroluminescence device according to claim 2, wherein any one of the organic thin film layers contains at least one of the styrylamine derivatives including an E-isomer represented by general formula 3 below with A₂ in the general formula 1 replaced by the general formula2 and a Z-isomer thereof.
Formula 3

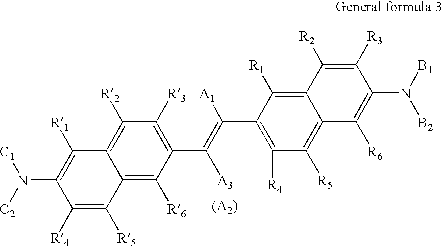

4. The organic electroluminescence device according to claim 3, wherein any one of the organic thin film layers contains at least one of the styrylamine derivatives including an E-isomer represented by general formula 4 below and a Z-isomer thereof.
Formula 4 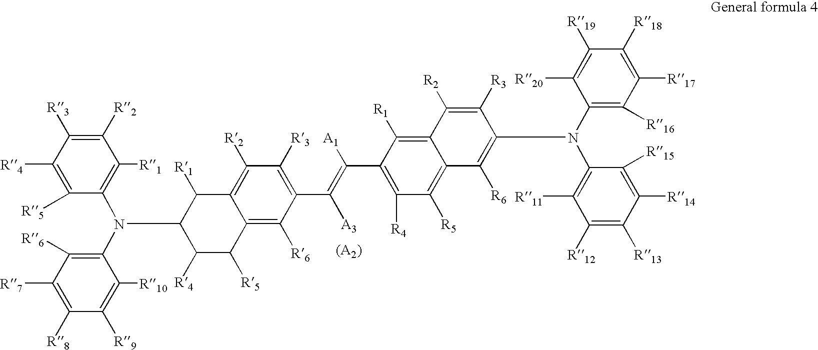
(wherein
R″₁ to R″₂₀ each independently represents
hydrogen, halogen, hydroxyl, cyano, nitro, amino,
a saturated or unsaturated hydrocarbon group,
a saturated or unsaturated hydrocarbon oxy group,
a substituted or unsubstituted aryl group,
a substituted or unsubstituted aryloxy group,
a substituted or unsubstituted heterocyclic group,
a saturated or unsaturated hydrocarbon amino group, or
a substituted or unsubstituted arylamino group,
where adjacent groups other than hydrogen, halogen, cyano, and nitro may join to each other to form a saturated or unsaturated carbon ring.)

5. The organic electroluminescence device according to claim 4, wherein any one of the organic thin film layers contains at least one of the styrylamine derivatives including an E-isomer represented by structural formula 1 below and a Z-isomer thereof.
Formula 5

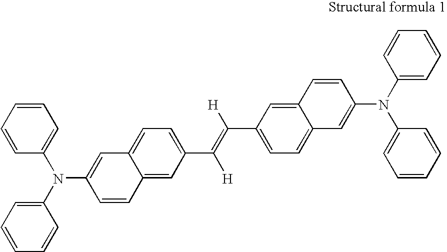

6. The organic electroluminescence device according to claim 4, wherein any one of the organic thin film layers contains at least one of the styrylamine derivatives including an E-isomer represented by structural formula 2 below and a Z-isomer thereof.
Formula 6

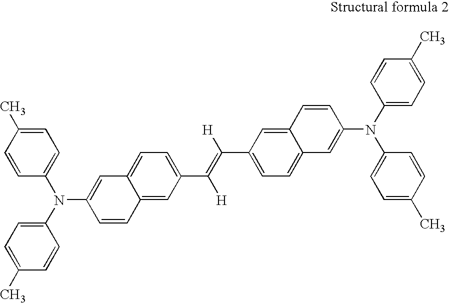

7. The organic electroluminescence device according to claim 4, wherein any one of the organic thin film layers contains at least one of the styrylamine derivatives including an E-isomer represented by structural formula 3 below and a Z-isomer thereof.
Formula 7

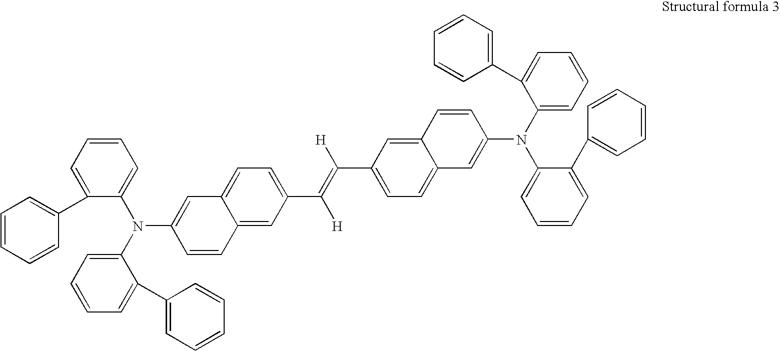

8. The organic electroluminescence device according to claim 1, wherein,
in the general formula 1 representing the styrylamine derivative,
R₁ to R₆ each independently represents
hydrogen, halogen, hydroxyl, cyano, nitro, amino,
a saturated or unsaturated hydrocarbon group having from 1 to 20 carbon atoms,
a saturated or unsaturated hydrocarbon oxy group having from 1 to 20 carbon atoms,
a substituted or unsubstituted aryl group having from 6 to 25 carbon atoms,
a substituted or unsubstituted aryloxy group having from 6 to 25 carbon atoms,
a substituted or unsubstituted heterocyclic group having from 2 to 25 carbon atoms,
a saturated or unsaturated hydrocarbon amino group having from 1 to 8 carbon atoms, or
a substituted or unsubstituted arylamino group having from 6 to 35 carbon atoms,
where adjacent groups other than hydrogen, halogen, cyano, and nitro may join to each other to form a saturated or unsaturated carbon ring, and
A₁ to A_{3,} B_{1,} and B₂ each independently represents hydrogen,
a saturated or unsaturated hydrocarbon group having from 1 to 20 carbon atoms,
a substituted or unsubstituted aryl group having from 6 to 45 carbon atoms, or
a substituted or unsubstituted heterocyclic group having from 2 to 30 carbon atoms,
where adjacent groups may join to each other to form a saturated or unsaturated carbon ring.

9. The organic electroluminescence device according to claim 1, wherein
the styrylamine derivative is contained in a blue light emitting layer of the luminescent layer; and
in the general formula 1 representing the styrylamine derivative contained in the luminescent layer,
R₁ to R₆ each independently represents
hydrogen, halogen, hydroxyl, cyano, nitro, amino,
a saturated or unsaturated hydrocarbon group having from 1 to 6 carbon atoms,
a saturated or unsaturated hydrocarbon oxy group having from 1 to 6 carbon atoms,
a substituted or unsubstituted aryl group having from 6 to 12 carbon atoms,
a substituted or unsubstituted aryloxy group having from 6 to 12 carbon atoms,
a substituted or unsubstituted heterocyclic group having from 2 to 10 carbon atoms,
a saturated or unsaturated hydrocarbon amino group having from 1 to 8 carbon atoms, or
a substituted or unsubstituted arylamino group having from 6 to 35 carbon atoms,
where adjacent groups other than hydrogen, halogen, cyano, and nitro may join to each other to form a saturated or unsaturated carbon ring,
A₁ to A₃ each independently represents
hydrogen,
a saturated or unsaturated hydrocarbon group having from 1 to 20 carbon atoms,
a substituted or unsubstituted aryl group having from 6 to 45 carbon atoms, or
a substituted or unsubstituted heterocyclic group having from 2 to 30 carbon atoms,
where adjacent groups may join to each other to form a saturated or unsaturated carbon ring, and
B₁ and B₂ each independently represents a substituted or unsubstituted aryl group having from 6 to 15 carbon atoms or
a substituted or unsubstituted heterocyclic group having from 2 to 15 carbon atoms,
where adjacent groups may join to each other to form a saturated or unsaturated carbon ring.

10. The organic electroluminescence device according to claim 9, wherein the styrylamine derivative is contained in the luminescent layer in the organic thin film layers at a concentration lower than 50% by volume.

11. A display apparatus formed by arranging on a substrate a plurality of organic electroluminescence devices having organic thin film layers provided between an anode and a cathode and including at least a luminescent layer, comprising:
a styrylamine derivative represented by general formula 1 below in any one of the organic thin film layers.
Formula 8 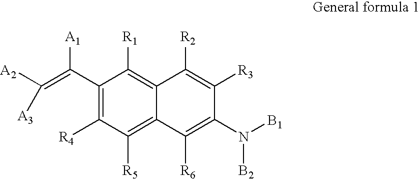
(wherein
R₁ to R₆ each independently represents
hydrogen, halogen, hydroxyl, cyano, nitro, amino,
a saturated or unsaturated hydrocarbon group,
a saturated or unsaturated hydrocarbon oxy group,
a substituted or unsubstituted aryl group,
a substituted or unsubstituted aryloxy group,
a substituted or unsubstituted heterocyclic group,
a saturated or unsaturated hydrocarbon amino group, or
a substituted or unsubstituted arylamino group,
where adjacent groups other than hydrogen, halogen, cyano, and nitro may join to each other to form a saturated or unsaturated carbon ring, and
A₁ to A_{3,} B_{1,} and B₂ each independently represents hydrogen,
a saturated or unsaturated hydrocarbon group,
a substituted or unsubstituted aryl group, or
a substituted or unsubstituted heterocyclic group,
where adjacent groups may join to each other to form a saturated or unsaturated carbon ring.)
